(19) United States
(12) Patent Application Publication
(10) Pub. No.: US 2025/0380554 A1
(43) Pub. Date: Dec. 11, 2025

(54) LIGHT-EMITTING DEVICE AND A MANUFACTURING METHOD THEREOF

(71) Applicant: HUIZHOU JUFEI OPTOELECTRONICS CO., LTD., Huizhou (CN)

(72) Inventors: Peng CHENG, Huizhou (CN); Wenbo MA, Huizhou (CN); Cheng TANG, Huizhou (CN); Panfeng TAN, Huizhou (CN); Youpu KE, Huizhou (CN); Pingru SUN, Huizhou (CN); Huahua LI, Huizhou (CN); Ming HUANG, Huizhou (CN); Ni ZHANG, Huizhou (CN); Meizheng XING, Huizhou (CN)

(73) Assignee: HUIZHOU JUFEI OPTOELECTRONICS CO., LTD., Huizhou (CN)

(21) Appl. No.: 19/300,216

(22) Filed: Aug. 14, 2025

Related U.S. Application Data
(63) Continuation of application No. PCT/CN2024/075834, filed on Feb. 4, 2024.

(30) Foreign Application Priority Data
Feb. 15, 2023 (CN) 202310129303.2
Feb. 17, 2023 (CN) 202310188688.X
Mar. 1, 2023 (CN) 202310191450.2
Apr. 26, 2023 (CN) 202320984543.6
Jul. 11, 2023 (CN) 202321826185.2

(51) Int. Cl. H10H 29/853; H01L 25/075; H10H 29/01; H10H 29/80; H10H 29/85; H10H 29/855

(52) U.S. Cl. CPC H10H 29/853; H01L 25/0753; H10H 29/0362; H10H 29/0363; H10H 29/0364; H10H 29/8421; H10H 29/8508; H10H 29/855; H10H 29/857

(57) ABSTRACT

This application relates to a light-emitting device and a manufacturing method thereof, comprising a substrate, a plurality of light-emitting chips arranged on the front side of the substrate, and an encapsulation layer disposed on the substrate to cover each light-emitting chip. The encapsulation layer allows light emitted by the LED chips to pass through.

### REFERENCE TO RELATED APPLICATIONS

The present application is a continuation of international application No. PCT/CN2024/075834, filed on Feb. 4, 2024, which claims the priority of CN application 202310129303.2, filed on Feb. 15, 2023, CN application No. 202310188688.X, filed on Feb. 17, 2023, CN application No. 202310191450.2, filed on Mar. 1, 2023, CN application No. 202320984543.6, filed on Apr. 26, 2023, and CN application No. 202321826185.2, filed on Jul. 11, 2023 the entirety of which are incorporated herein by reference.

### TECHNICAL FIELD

This application relates to the field of LEDs (Light Emitting Diode, LED chips), particularly to a light-emitting device and a manufacturing method thereof.

### BACKGROUND

LED light-emitting devices are widely used in fields such as display modules and lighting modules. Both the display and lighting industries impose strict requirements on the sealing performance of LEDs and the thickness of light-emitting devices made from them. To meet sealing requirements, the display industry typically uses LED lamps with better sealing, which include a bracket, an LED chip placed inside the bracket, and a sealing adhesive layer that encapsulates the LED chip within the bracket. Although LED lamps can satisfy sealing needs, their use of LED brackets results in larger dimensions and higher costs, this consequently leads to display modules made with LED chips being bulkier overall and more costly.

### SUMMARY

In view of the limitations of the prior art, the objective of this application is to provide a light-emitting device and a manufacturing method thereof, aiming to address issues in related technologies where the device is overly thick and costly.

To solve the above problems, this application provides a light-emitting device, comprising a substrate, a plurality of light-emitting chips arranged on the substrate, and an encapsulation layer covering the light-emitting chips. The light emitted by the light-emitting chips exits through the encapsulation layer.

Based on the same inventive concept, this application further provides a method for manufacturing a light-emitting device, comprising the following steps of:
providing a substrate;
arranging a plurality of light-emitting chips on a front side of the substrate;
forming an encapsulation layer on the substrate to cover each of the light-emitting chips, wherein the encapsulation layer allows light from the light-emitting chips to pass through.

### Advantageous Effects

The light-emitting device and a manufacturing method thereof provided in this application include a substrate, light-emitting chips arranged on the substrate, and an encapsulation layer covering the chips. Instead of using LED lamps as the light source, this device directly employs light-emitting chips, eliminating the need for brackets used in LED lamps. This not only reduces costs but also decreases the overall thickness of the device, making it more compact. The encapsulation layer covering the chips meets sealing requirements in display and lighting applications while also providing protection for the chips.

### BRIEF DESCRIPTION OF DRAWINGS

FIG. 1 is a cross-sectional schematic of a substrate corresponding to a single set of light-emitting chips in Embodiment 1 of this application;

FIG. 2-1 is a top-view schematic of the arrangement of a first circuit layer in Embodiment 1 of this application;

FIG. 2-2 is another top-view schematic of the arrangement of a first circuit layer in Embodiment 1 of this application;

FIG. 2-3 is a top-view schematic of the arrangement of a fixing groove in Embodiment 1 of this application;

FIG. 2-4 is another top-view schematic of the arrangement of a fixing groove in Embodiment 1 of this application;

FIG. 2-5 is a schematic cross-sectional view of another substrate provided in Embodiment 1 of the present application;

FIG. 2-6 is a schematic top view of yet another arrangement of a fixing groove provided in Embodiment 1 of the present application;

FIG. 2-7 is a schematic cross-sectional view of yet another arrangement of a fixing groove provided in Embodiment 1 of the present application;

FIG. 2-8 is a second schematic cross-sectional view of a backlight device corresponding to a single set of light-emitting chips provided in Embodiment 1 of the present application;

FIG. 2-9 is a schematic cross-sectional view of another backlight device provided in Embodiment 1 of the present application;

FIG. 2-10 is a top view of a substrate corresponding to a plurality of sets of light-emitting chips provided in Embodiment 1 of the present application;

FIG. 2-11 is a schematic top view of another arrangement of a fixing groove provided in Embodiment 1 of the present application;

FIG. 2-12 is a schematic top view of another arrangement of a fixing groove provided in Embodiment 1 of the present application;

FIG. 3-1 is a schematic side view of a display module corresponding to a single set of light-emitting chips provided in Embodiment 2 of the present application;

FIG. 3-2 is a schematic diagram of one arrangement method of a reinforcing member in the display module provided in Embodiment 2 of the present application;

FIG. 3-3 is a schematic diagram of another arrangement of the reinforcing member in the display module provided in Embodiment 2 of the present application;

FIG. 3-4 is a schematic diagram of yet another arrangement of the reinforcing member in the display module provided in Embodiment 2 of the present application;

FIG. 3-5 is a schematic diagram of yet another arrangement of the reinforcing member in the display module provided in Embodiment 2 of the present application;

FIG. 3-6 is a schematic diagram of yet another arrangement of the reinforcing member in the display module provided in Embodiment 2 of the present application;

FIG. 3-7 is a schematic cross-sectional view of A-A in FIG. 3-1 provided in Embodiment 2 of the present application;

FIG. 3-8 is a schematic side view of another display module structure provided in Embodiment 2 of the present application;

FIG. 3-9 is a schematic side view of yet another display module structure provided in Embodiment 2 of the present application;

FIG. 4-1 is a schematic front view of a display module for splicing provided in Embodiment 3 of the present application;

FIG. 4-2 is a schematic cross-sectional view of B-B in FIG. 4-1 in one example of Embodiment 3 of the present application;

FIG. 4-3 is a schematic cross-sectional view of the display module in another example of Embodiment 3 of the present application;

FIG. 4-4 is a schematic cross-sectional view of B-B in FIG. 4-1 in another example of Embodiment 3 of the present application;

FIG. 4-5 is a schematic cross-sectional view of the display module in another example of Embodiment 3 of the present application;

FIG. 4-6 is a schematic cross-sectional view of the display module in another example of Embodiment 3 of the present application;

FIG. 4-7 is a schematic cross-sectional view of the display module in another example of Embodiment 3 of the present application;

FIG. 4-8 is a schematic cross-sectional view of the display module in another example of Embodiment 3 of the present application;

FIG. 4-9 is a schematic cross-sectional view of the display module in another example of Embodiment 3 of the present application;

FIG. 4-10 is a schematic structural diagram of the C-C cross-section in FIG. 4-11;

FIG. 4-11 is a schematic structural diagram of the substrate in the manufacturing method of the display module provided in Embodiment 3 of this application;

FIG. 4-12 is a schematic structural diagram of the substrate with a circuit layer and a circuit protection layer arranged in Embodiment 3 of this application;

FIG. 4-13 is a schematic structural diagram of the carrier board arranged at the edge of the substrate in Embodiment 3 of this application;

FIG. 4-14 is a schematic structural diagram of the mold and encapsulation adhesive layer film arranged on the substrate in Embodiment 3 of this application;

FIG. 4-15 is a schematic structural diagram of the third encapsulation adhesive layer being hot-pressed onto the substrate in Embodiment 3 of this application;

FIG. 4-16 is a schematic structural diagram of the substrate after the third encapsulation adhesive layer is hot-pressed in Embodiment 3 of this application;

FIG. 4-17 is a schematic structural diagram of another example of the substrate after the third encapsulation adhesive layer is hot-pressed in Embodiment 3 of this application;

FIG. 4-18 is a schematic structural diagram of another example of the third encapsulation adhesive layer being hot-pressed onto the substrate in Embodiment 3 of this application;

FIG. 4-19 is a schematic structural diagram of another example of the substrate after the third encapsulation adhesive layer is hot-pressed in Embodiment 3 of this application;

FIG. 4-20 is a schematic structural diagram of another example of the substrate after the third encapsulation adhesive layer is hot-pressed in Embodiment 3 of this application;

FIG. 4-21 is the first schematic structural diagram of the carrier board arranged on the side of the substrate in Embodiment 3 of this application;

FIG. 4-22 is the second schematic structural diagram of the carrier board arranged on the side of the substrate in Embodiment 3 of this application;

FIG. 4-23 is the third schematic structural diagram of the carrier board arranged on the side of the substrate in Embodiment 3 of this application;

FIG. 4-24 is the fourth schematic structural diagram of the carrier board arranged on the side of the substrate in Embodiment 3 of this application;

FIG. 4-25 is a front schematic structural diagram of the display screen after the display module provided in Embodiment 3 of this application is assembled;

FIG. 4-26 shows the schematic structural diagram of the D-D cross-section in FIG. 4-25;

FIG. 4-27 shows the schematic cross-sectional structure of a prior-art display module;

FIG. 4-28 shows the schematic structural diagram of a carrier board arranged on the side of the substrate in another example of Embodiment 3 of this application;

FIG. 4-29 shows the schematic diagram of the E-E cross-section in FIG. 4-28;

FIG. 4-30 shows the schematic cross-sectional structure of the display module in another example of Embodiment 3 of this application;

FIG. 5-1 is the schematic cross-sectional structure of the display module provided in Embodiment 4 of this application;

FIG. 5-2 is the schematic diagram of the position of the second pad area in the display module provided in Embodiment 4 of this application;

FIG. 5-3 is the schematic structural diagram of the first reflective film layer in the display module provided in Embodiment 4 of this application;

FIG. 6-1 shows the schematic structural diagram of an existing display module;

FIG. 6-2 shows the first schematic structural diagram of the display module provided in Embodiment 5 of this application;

FIG. 6-3 shows the schematic structural diagram of the substrate provided in Embodiment 5 of this application;

FIG. 6-4 shows the first schematic structural diagram of the substrate with a filling layer provided in Embodiment 5 of this application;

FIG. 6-5 shows the second schematic structural diagram of the substrate with a filling layer provided in Embodiment 5 of this application;

FIG. 6-6 shows the third schematic structural diagram of the substrate with a filling layer provided in Embodiment 5 of this application;

FIG. 6-7 shows the fourth schematic structural diagram of the substrate with a filling layer provided in Embodiment 5 of this application;

FIG. 6-8 shows the schematic structural diagram of the second reflective film layer provided in Embodiment 5 of this application;

FIG. 6-9 is a second schematic diagram of the display module structure provided in Embodiment 5 of the present application;

FIG. 6-10 is a third schematic diagram of the display module structure provided in Embodiment 5 of the present application.

### DESCRIPTION OF EMBODIMENTS

To facilitate understanding of the present application, a more comprehensive description will be provided below with reference to the accompanying drawings. Preferred embodiments of the present application are shown in the drawings. However, the present application can be implemented in many different forms and is not limited to the embodiments described herein. On the contrary, these embodiments are provided to make the disclosure of the present application more thorough and comprehensive.

Unless otherwise defined, all technical and scientific terms used herein have the same meanings as commonly understood by those skilled in the technical field of the present application. The terms used in the specification of the present application are only for the purpose of describing specific embodiments and are not intended to limit the present application.

It should be noted that the terms “first,” “second,” etc., in the specification and claims of the present application and the above-mentioned drawings are used to distinguish similar objects and are not necessarily used to describe a specific order or sequence. It should be understood that the data used in this way can be interchanged under appropriate circumstances to describe the embodiments of the present application herein. In addition, the terms “comprising” and “having” and any variations thereof are intended to cover non-exclusive inclusion. For example, a process, method, system, product, or device that includes a series of steps or units is not necessarily limited to those steps or units explicitly listed but may include other steps or units not explicitly listed or inherent to such processes, methods, products, or devices.

In the present application, the terms “upper,” “lower,” “inner,” “middle,” “outer,” “front,” “rear,” etc., indicate orientations or positional relationships based on those shown in the accompanying drawings. These terms are mainly used to better describe the present application and its embodiments and are not intended to limit the indicated devices, components, or parts to specific orientations or to be constructed and operated in specific orientations. Moreover, some of the above terms may also be used to indicate other meanings besides orientations or positional relationships. For example, the term “upper” may in some cases also indicate a certain dependency or connection relationship. For those skilled in the art, the specific meanings of these terms in the present application can be understood according to the context. In addition, the terms “arranged,” “connected,” and “fixed” should be understood broadly. For example, “connected” can mean a fixed connection, a detachable connection, or an integral structure; it can be a mechanical connection or an electrical connection; it can be a direct connection or an indirect connection through an intermediary, or it can be an internal connection between two devices, components, or parts. For those skilled in the art, the specific meanings of the above terms in the present application can be understood according to the context.

It should be noted that, in the absence of conflict, the embodiments in the present application and the features in the embodiments can be combined with each other. The present application will be described in detail below with reference to the drawings and in conjunction with the embodiments.

This application provides a light-emitting device, which can be applied to various fields such as home displays, medical displays, decorative displays, traffic displays, and advertising displays. For example, it can be specifically applied to various electronic devices, including but not limited to displays, mobile terminals, computers, wearable devices, advertising equipment, and vehicle-mounted equipment. It can also be used in the lighting field, such as flat light panels, traffic indicator lights, or backlight panels. Therefore, the light-emitting device can be a display module or a lighting module. For brevity, the following embodiments will use the display module as an example for explanation.

The display module in this embodiment includes a substrate, several light-emitting chips, and an encapsulation layer.

In this application, the substrate can serve as the backplate of the display module or as an independent carrier substrate for supporting the light-emitting chips. The substrate can be a single-layer substrate or a composite substrate comprising at least two layers. It can be a flexible substrate or a rigid substrate, which is not limited in this embodiment.

The light-emitting chips are arranged on the substrate. The light-emitting chips included in this application may include but are not limited to micron-level LED chips (e.g., Mini LED chips or Micro LED chips), such as micron-level flip-chip LED chips. Of course, all or part of them can also be replaced with micron-level wire bonding or vertical LED chips. In terms of size, they can also be replaced with LED chips larger than Mini LED chips as needed. The light-emitting color of the chips can be flexibly set according to specific application requirements.

The encapsulation layer is placed on the substrate, covering all the light-emitting chips and allowing the light emitted by them to pass through. The encapsulation layer may only cover the side of the substrate where the light-emitting chips are located, either fully or partially. It may also extend from this side to at least one lateral side of the substrate or even to the back of the substrate. The encapsulation layer can be a single-layer structure or a multi-layer structure comprising at least two layers.

It is evident that the display module structure provided in this application is flexible and versatile, suitable for a wide range of scenarios. Moreover, while meeting sealing requirements, it has a smaller overall thickness and lower cost. For ease of understanding, the following sections will illustrate some specific structural variations and manufacturing methods with reference to various embodiments.

### Embodiment 1

In related technologies, display modules are evolving toward Mini LED, with COB (Chip on Board) packaging technology already seeing a certain range of applications. However, for existing COB-packaged backlight products, the process typically involves flip-mounting conventional blue LED chips onto a substrate and then dispensing encapsulant on the LED chips to form lenses. To protect the circuit layer on the substrate and enhance the brightness of the backlight product, a solder resist layer is usually applied on top of the substrate. The smooth surface of the solder resist layer results in poor adhesion between the lens and the substrate, making the lens prone to detachment during product handling, thereby affecting the display performance of the backlight product. Therefore, improving the adhesion between the lens and the substrate in backlight products to ensure display quality is an urgent issue to address.

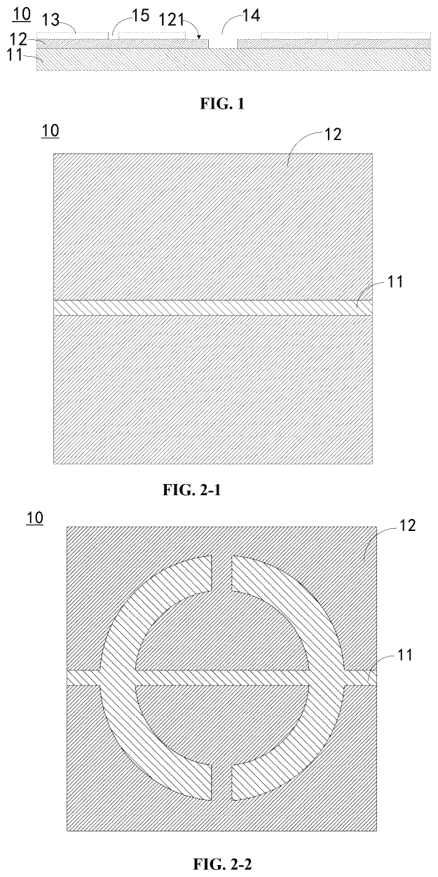

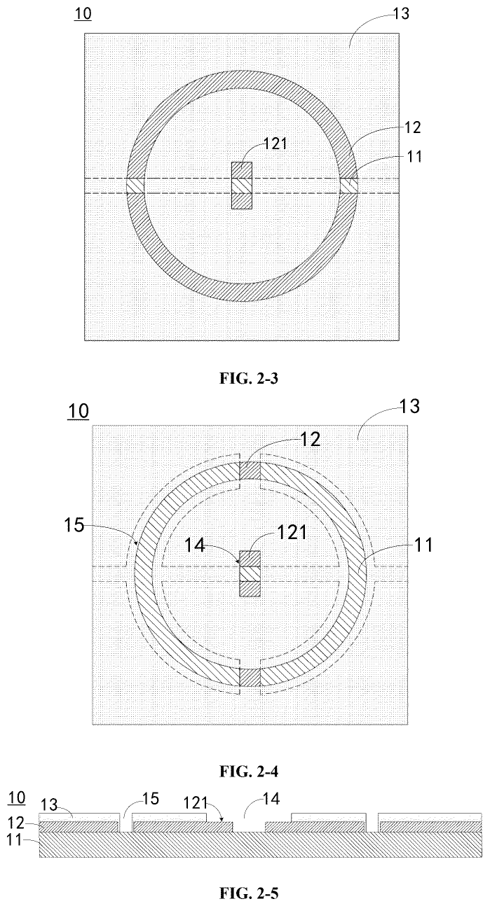

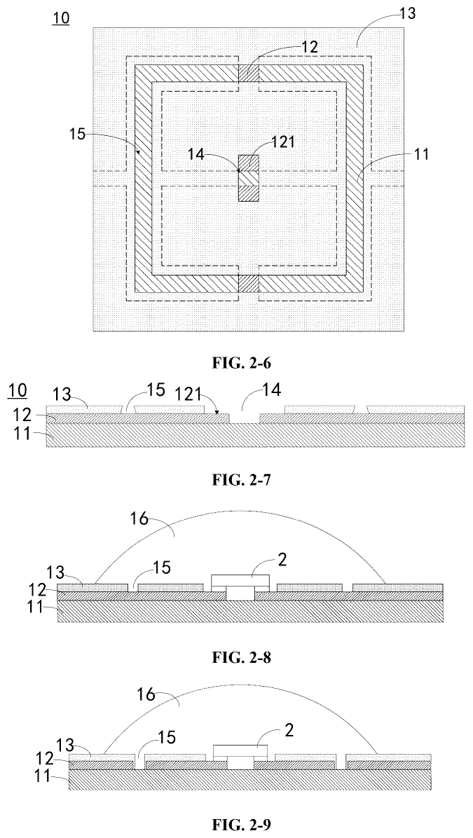

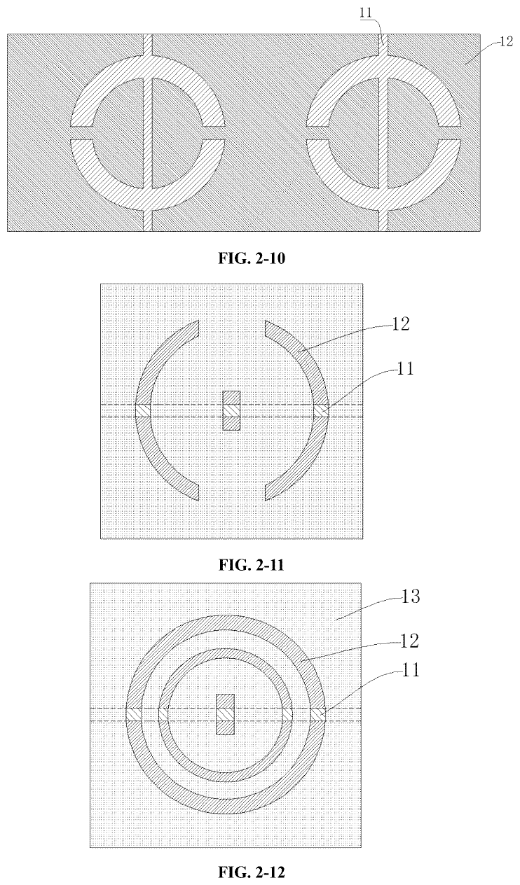

This embodiment provides a substrate that can solve the above problem and a display module manufactured using this substrate. Referring to FIG. 1, which shows a cross-sectional schematic of the substrate 10 corresponding to a single set of light-emitting chips, and FIGS. 2-10, which show top views of the substrate 10 corresponding to two sets of light-emitting chips (with substrates for more than two sets following the same logic), the substrate 10 includes a first insulating base layer 11, a first circuit layer 12, and a solder resist layer 13 stacked in sequence. The first circuit layer 12 is provided with a plurality of sets of first pads 121. The solder resist layer 13 is provided with several window openings 14 corresponding to the first pads 121, with each set of first pads 121 exposed through their respective window openings 14. The window openings 14 are configured to allow the light-emitting chips to electrically connect with the corresponding first pads 121. The solder resist layer 13 also includes several fixing grooves 15, each surrounding a respective window opening 14. The encapsulation layer in this embodiment consists of a first encapsulation adhesive layer formed by a plurality of first lenses. The first lenses are formed by filling a first encapsulant above the corresponding window openings 14, with part of the first encapsulant forming the first lenses accommodated in the fixing grooves 15. In other words, the fixing grooves 15 are configured to accommodate part of the first encapsulant when forming the first lenses by filling the first encapsulant above the corresponding window openings 14.

In this embodiment, the first insulating base layer 11 primarily determines the strength and form of the substrate. The material of the first insulating base layer 11 can be glass, ceramic, resin, etc., and it is formed at the bottommost layer of the substrate 10.

The first circuit layer 12 can be achieved by, but not limited to, laying copper foil. A copper foil layer is first placed on the first insulating base layer 11, and then the desired circuits are etched onto the copper foil through an etching process, including but not limited to separating the positive and negative electrode circuits. This also includes etching the first pads 121 for fixing components such as light-emitting chips, capacitors, and resistors. Refer to FIG. 2-1 or FIG. 2-2, both of which illustrate the structure of separating positive and negative electrode circuits when forming the first circuit layer 12. FIG. 2-1 directly uses a through-line to separate the positive and negative electrodes, while FIG. 2-2, in addition to separating the positive and negative electrodes, also creates corresponding hollow patterns on the first circuit layer 12 based on the shape of the intended fixing groove 15, allowing the fixing groove 15 to extend downward to the first insulating base layer 11. Of course, it should be understood that the first circuit layer 12 can also be fabricated through various other circuit layer formation processes, such as magnetron sputtering or printing.

In this embodiment, to protect the circuits on the first circuit layer 12, a solder resist layer 13 is added above the first circuit layer 12. The function of the solder resist layer 13 is to cover the parts of the first circuit layer 12 that do not need to be exposed, thereby reducing the impact of external factors on the first circuit layer 12. For positions requiring external circuit connections, such as the first pad 121 areas on the first circuit layer 12, the solder resist layer 13 must avoid covering these areas while covering the first circuit layer 12, resulting in the window openings 14 set on the solder resist layer 13. The purpose of the window openings 14 is to expose the corresponding first pads 121, allowing components like light-emitting chips that need to connect to the first pads 121 to access them at the window openings 14 and establish electrical connections with the first pads 121.

The size of the window openings 14 on the first pads 121 can be determined based on factors such as the dimensions of the light-emitting chips to be installed and the size of their pins. Generally, the size of the window openings 14 only needs to ensure that the pins of the light-emitting chips can maintain normal connections with the first pads 121.

In addition to protecting the first circuit layer 12, the solder resist layer 13 can also serve as a reflective layer, reflecting light emitted by the light-emitting chips arranged on the display module, thereby enhancing the overall brightness and uniformity of the display module's light output. In this case, the solder resist layer 13 can specifically be implemented using a high-reflectivity white solder mask.

In the subsequent process of forming the display module using the substrate 10, the first encapsulant can be filled in the window opening 14 to form the first lens. However, due to the relatively smooth surface of the solder resist layer 13, the bonding strength between the first lens and the solder resist layer 13 is weak, causing the first lens to easily detach during the transportation of the display module. To address this issue, as shown in FIGS. 2-4, this embodiment incorporates fixing grooves 15 on the solder resist layer 13. These fixing grooves 15 are arranged around the window opening 14, meaning they are formed on the periphery of the window opening 14. The fixing grooves 15 are recessed structures that sink from the surface of the solder resist layer 13 into its interior, creating accommodating slots. These slots can hold the first encapsulant filled to form the first lens. Specifically, when filling the first encapsulant, part of it flows into the fixing grooves 15 and integrates with the first encapsulant placed above the window opening 14. By introducing the fixing grooves 15, the contact area between the first encapsulant of the first lens and the substrate 10 is increased compared to structures without such grooves. This enhances the bonding area between the first encapsulant and the substrate 10, thereby improving their bonding strength and reducing the likelihood of the first lens detaching from the substrate 10. Additionally, since part of the first encapsulant fills the fixing grooves 15, the groove walls restrict the relative movement of the encapsulant in the shear direction between the first lens and the substrate 10, further minimizing the risk of detachment.

The fixing grooves 15 are formed by recessing downward from the surface of the solder resist layer 13. Depending on the depth of the recess, the bottom extension of the fixing grooves 15 varies. For example, in some optional embodiments, the bottom of the fixing grooves 15 may extend to the first circuit layer 12 or the first insulating base layer 11. In the layered structure of the substrate 10, the solder resist layer 13 is the topmost layer, followed by the first circuit layer 12 beneath it, and then the first insulating base layer 11 below that. Thus, the fixing grooves 15 can extend sequentially to the first circuit layer 12 or the first insulating base layer 11. The deeper the extension into the first circuit layer 12, the more first encapsulant can fill the fixing grooves 15 during the formation of the first lens. A greater amount of filled encapsulant increases the contact area between the first encapsulant and the fixing grooves 15, thereby improving the bonding effect between the first lens and the substrate.

The bottom of the fixing groove 15 extends to the first circuit layer 12, meaning the fixing groove 15 can extend to any position within the range from the top to the bottom of the first circuit layer 12, as long as it does not damage the necessary circuit connections on the first circuit layer 12, as shown in FIG. 1. On the other hand, the bottom of the fixing groove 15 extending to the first insulating base layer 11 indicates that the fixing groove 15 must also pass through the first circuit layer 12 located above the first insulating base layer 11, resulting in a greater depth compared to extending only to the first circuit layer 12, as shown in FIGS. 2-5. Similarly, the bottom of the fixing groove 15 extending to the first insulating base layer 11 can specifically mean that the bottom of the fixing groove 15 extends to any position within the range from the top to the bottom of the first insulating base layer 11.

Compared to the fixing groove 15 extending only to the first circuit layer 12, having it pass through the first circuit layer 12 and extend directly to the first insulating base layer 11 can reduce heat generation in the circuits of the first circuit layer 12 during operation, thereby preventing thermal deformation of the first encapsulant and improving its reliability.

Additionally, the fixing groove 15 can also be set solely within the solder resist layer 13, meaning the bottom of the fixing groove 15 remains within the solder resist layer 13. This arrangement can, to some extent, enhance the bonding strength between the first lens and the substrate 10. The deeper the bottom of the fixing groove 15 extends, the stronger the bonding effect between the first lens and the substrate 10.

In some optional examples, the bottom of the fixing groove 15 extends to the first insulating base layer 11. To ensure the stability of the connection between the solder resist layer 13 and the first circuit layer 12, the solder resist layer 13 at the edge of the fixing groove 15 can extend toward the first insulating base layer 11 to cover the first circuit layer 12, as shown in FIGS. 2-5. In other words, the solder resist layer 13 can wrap around the edges of the first circuit layer 12, thereby improving the adhesion between the solder resist layer 13 and the first circuit layer 12 and preventing the solder resist layer 13 from peeling off.

In some optional examples, to further enhance the bonding between the first lens and the substrate 10, at least one of the plurality of fixing grooves 15 may include a closed annular groove. Here, the closed annular groove refers to a fixing groove 15 with an open top and closed bottom and sides. Among them, the fixing groove 15 shown in FIG. 2-9 is arranged around the window opening 14. This surrounding arrangement can involve a plurality of separate fixing grooves 15 distributed in a ring-like manner, encircling the window opening 14 like stars surrounding the moon. The fixing groove 15 shown in FIG. 2-11 is itself an annular groove, directly surrounding the window opening 14. Notably, when the fixing groove 15 is a closed annular groove, the first encapsulant formed within the fixing groove 15 becomes a unified annular first encapsulant. The first encapsulant can bond with the bottom and sides of the fixing groove, further enhancing the bonding between the first lens and the substrate 10, while also reducing the impact of thermal expansion and contraction of the first encapsulant on the adhesion between the first lens and the substrate 10.

A closed annular groove completely severs the interior and exterior of the annular groove. If the bottom of the annular groove extends to the first insulating base layer 11, it will create a completely severed area in the first circuit layer 12, potentially affecting the circuits on the first circuit layer 12. To address this issue, possible solutions include but are not limited to: setting the annular groove on the first circuit layer 12 as non-closed, ensuring the first circuit layer 12 remains connected, as shown in FIG. 2-4; or alternatively, adding circuits at other locations on the first insulating base layer 11 or first circuit layer 12. If the closed annular groove does not extend to the first insulating base layer 11, it can be normally set within the first circuit layer 12.

In some optional examples, there may be a plurality of fixing grooves 15. When a plurality of fixing grooves 15 are set, they may include at least two annular grooves arranged sequentially in a nested manner. These annular grooves are distributed outward in order of their size, forming an inner annular groove and an outer annular groove, as shown in FIG. 2-12. Setting a plurality of fixing grooves 15 can significantly enhance the bonding between the first lens and the substrate 10.

In some optional examples, the shape of the fixing groove 15 can be a regular figure, typically circular or square annular, with the corresponding window opening 14 located at the center region of the fixing groove 15, as shown in FIG. 2-6. Positioning the window opening 14 at the center of the fixing groove 15 ensures uniform display effects for the light-emitting chips across the lamp board, thereby further guaranteeing the display consistency of the entire display module.

To ensure stable improvement in the bonding strength between the first lens and the substrate 10 when setting the fixing groove 15 and to maintain the light output effect of the display module, in some optional examples, the minimum width of the fixing groove 15 is 0.1 mm, and the maximum width is 1.0 mm. If the width of the fixing groove 15 is too large, the direct impact is a reduction in the area of the solder resist layer 13 serving as the reflective surface, which may affect the display effect of the display module, reducing its brightness. Conversely, if the width of the fixing groove 15 is too small, the bonding strength between the fixing groove 15 and the light panel will correspondingly decrease, and the first encapsulant may even fail to enter the fixing groove 15 due to the surface tension of the first encapsulant. Therefore, the width of the fixing groove 15 should ideally be within an appropriate range, ensuring both display performance and enhanced bonding strength between the first lens and the substrate 10.

In some optional examples, to further improve the bonding strength between the first lens and the substrate 10, the bottom width of the fixing groove 15 can be set greater than the top width, as shown in FIG. 2-7. The opening of the fixing groove 15 is located at the top, therefore if the first encapsulant within the fixing groove 15 is to detach, it must do so from the top. By setting the bottom width of the fixing groove 15 greater than the top width, the first encapsulant filled in the fixing groove 15 will be restricted by the smaller top width, preventing it from easily detaching. This creates a positional limit against relative vertical movement between the first lens and the substrate 10, in addition to adhesion, preventing the first lens from moving upward relative to the substrate 10, thereby further enhancing their bonding strength.

In the structure where the bottom width of the fixing groove 15 is greater than the top width, the sidewalls of the fixing groove 15 can be flat, continuous curved surfaces, or irregular surfaces, as long as they effectively restrict the upward movement of the first encapsulant.

The substrate 10 provided in this embodiment features a fixing groove 15 surrounding the window opening 14 on the solder resist layer 13 at the top of the substrate 10. When filling the first encapsulant to form the first lens, part of the first encapsulant is accommodated in the fixing groove 15, thereby increasing the bonding area between the first lens and the substrate 10. Additionally, a positional limit effect beyond adhesion is achieved in the shear direction between the first lens and the substrate 10, significantly reducing the likelihood of detachment and strengthening the bonding force between the first lens and the substrate 10.

This embodiment also provides a display module. Please refer to FIGS. 2-8 and 2-9, which include several sets of light-emitting chips 2, a first lens 16, and the substrate described in various embodiments of this application. Here, each set of light-emitting chips 2 is respectively placed in the corresponding window openings on the substrate and electrically connected to the corresponding first pads. Each first lens 16 is formed by filling the first encapsulant above the corresponding window opening, with a portion of the first encapsulant forming the first lens 16 filling into the fixing groove 15.

The display module in this embodiment is based on the structure of the aforementioned substrate. In addition to the substrate, it at least includes the light-emitting chips 2 arranged on the substrate and the first lens 16 enveloping the light-emitting chips 2. The light-emitting chips 2 are arrayed on the substrate. The light-emitting chips 2 on the substrate can be grouped individually or multiple of them are configured as one group, with each group corresponding to the same first lens 16. In other words, one first lens 16 can envelope one group of light-emitting chips 2. The number of light-emitting chips 2 in each group may be the same or partially the same and partially different.

The placement of the light-emitting chips 2 is at the locations of the window openings set on the solder resist layer 13. In this embodiment, the light-emitting chips 2 are placed within the window openings, meaning the fixation and electrical connection between the light-emitting chips 2 and the first circuit layer 12 are established within the range of the window openings on the first circuit layer 12. This does not restrict the size of the light-emitting chips 2 to be smaller than the window openings. In fact, as long as the pin range of the light-emitting chips 2 can pass through the window openings and connect electrically to the corresponding first pads, it is sufficient.

To adjust optical parameters, such as the light emission angle and brightness of the light-emitting chips 2, the first lens 16 can be placed over the light-emitting chips 2 to envelope the light-emitting chips 2. This allows the light emitted by the light-emitting chips 2 to refract through the first lens 16, altering its optical path. Additionally, materials like phosphors or QD quantum dots within the first lens 16 can be used to modify the color. To enhance the bonding between the first lens 16 and the substrate, when filling the first encapsulant into the window openings of the substrate to form the first lens 16, a portion of this encapsulant flows along the substrate surface to fill the fixing groove 15. This achieves an integrated molding of encapsulating the light-emitting chips 2 and filling the fixing groove 15 with the first encapsulant, thereby strengthening the bond between the first lens 16 and the substrate.

Depending on the varying depths of the fixing groove 15 set on the substrate, the depth of the first encapsulant corresponding to the first lens 16 also differs. The greater the depth, the deeper the first encapsulant fills, resulting in a stronger adhesion between the first lens 16 and the substrate. As shown in FIG. 2-8, the bottom of the fixing groove 15 extends to the first circuit layer 12, and correspondingly part of the first encapsulant of the first lens 16 also fills up to the first circuit layer 12. As shown in FIG. 10, the bottom of the fixing groove 15 extends to the first insulating base layer 11, and the corresponding first encapsulant of the first lens 16 also fills up to the first insulating base layer 11.

In the aforementioned display module, by setting the fixing groove 15 around the window opening on the solder resist layer 13 at the top of the substrate, part of the first encapsulant of the first lens 16 fills into the fixing groove 15. This increases the bonding area between the first lens 16 and the substrate and achieves a positioning effect in the shear direction beyond adhesion, significantly reducing the likelihood of the first lens 16 detaching from the substrate and enhancing the bonding strength of the first lens 16 with the substrate.

This embodiment also provides a method for manufacturing a display module, including the following steps:

S101: a substrate is provided, which includes a sequentially stacked first insulating base layer, first circuit layer, and solder resist layer. The first circuit layer is equipped with a plurality of sets of first pads, and the solder resist layer has a plurality of window openings corresponding to the first pads, exposing each set of first pads through the corresponding window opening. The solder resist layer also features a plurality of fixing grooves, each surrounding a window opening.

In this embodiment, during the fabrication of the substrate, a first insulating base layer is first provided, followed by forming the first circuit layer on the first insulating base layer, and then the solder resist layer is formed above the first circuit layer.

For the window openings set on the solder resist layer, they can be formed by removing the solder resist material corresponding to the positions of the first pads on the first circuit layer after creating a fully covered solder resist layer. Alternatively, the solder resist layer can be directly formed while avoiding the window opening locations. As for the fixing grooves on the solder resist layer, their formation methods vary depending on the extension position of the groove bottom, as detailed below:

When the bottom of the fixing groove is only within the solder resist layer and extends to the bottom of the solder resist layer, the fixing groove can be formed by referring to the method used for creating the window openings.

When the bottom of the solder resist layer extends into the first circuit layer until reaching its bottom, the initial form of the fixing groove can be pre-set at the corresponding position on the first circuit layer during its fabrication. Subsequently, the solder resist layer is formed above the first circuit layer, allowing it to follow the pre-set initial form of the fixing groove and extend downward along the edge of the first circuit layer to the first insulating base layer below, thereby wrapping the edge of the first circuit layer. Alternatively, the fixing groove can be integrally formed after both the first circuit layer and the solder resist layer have been completed.

S102: several light-emitting chips are fixed and arranged within the window openings and are electrically connected to the corresponding first pads.

According to the grouping of the light-emitting chips, the fixed and electrical connections of the chips can be achieved within the respective window openings. The connection between the light-emitting chips and the first pads is typically achieved through methods such as soldering or conductive adhesive bonding. For flip-chip LED chips, the fixed and electrical connections are usually integrated. Specifically, the flip-chip LED chips can be soldered onto the first pads using solder paste through reflow soldering, completing both the fixed and electrical connections simultaneously. For conventional wire bonding LED chips, wire bonding is required to achieve the electrical connection.

S103: the corresponding window openings are filled with the first encapsulant to integrally form the first lens, with a portion of the first encapsulant filling the fixing grooves.

Filling the first encapsulant above the window openings to form the first lens refers to the position of the filling being at the location of the window openings. This does not mean the first encapsulant is confined only to the area of the window openings. In fact, the first encapsulant must cover and extend beyond the window openings to allow a portion of it to flow naturally and fill the fixing grooves.

The process of filling the first encapsulant can be achieved using a high-precision dispensing machine, followed by high-temperature baking for curing and shaping.

The above display module manufacturing method involves setting fixing grooves around the window openings on the solder resist layer at the top of the substrate. This allows a portion of the first encapsulant of the first lens to fill the fixing grooves, thereby increasing the bonding area between the first lens and the substrate. Additionally, it achieves a limiting effect in the shear direction beyond mere adhesion for the first lens and the substrate, significantly reducing the likelihood of the first lens detaching from the substrate and enhancing the bonding strength between the two.

### Embodiment 2

In related technologies, such as the field of LED packaging for lighting, backlight modules, direct-display LED packaging, and UV LED packaging, many products require varying emission angles, light patterns, and protective measures for chip encapsulation. Typically, achieving these different angles, light patterns, or chip protection involves encapsulating the light-emitting chips with a layer of optical material or chip protection material of a specific shape through processes like molding, injection molding, or dispensing. This aims to achieve the desired angle, light pattern, or chip protection. However, some of these encapsulation materials lack or have weak adhesiveness, requiring auxiliary fixation methods such as glue or clamping. Even materials with good adhesiveness risk detachment from the substrate. Therefore, enhancing the bonding strength of encapsulation materials in the field of light-emitting chip packaging and reducing the risk of detachment are urgent issues to address.

To address the aforementioned issues, this embodiment provides a novel display module. It should be understood that the display module in this embodiment can be implemented independently of other embodiments and, where no conflict arises, can be combined with other embodiments. For ease of understanding, the following provides an exemplary description of this display module.

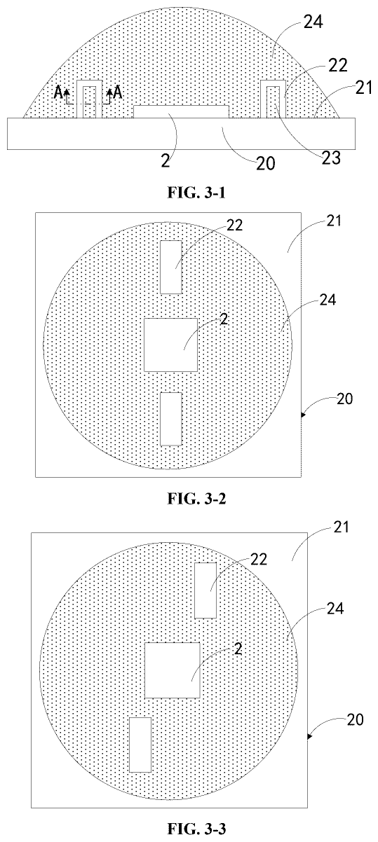

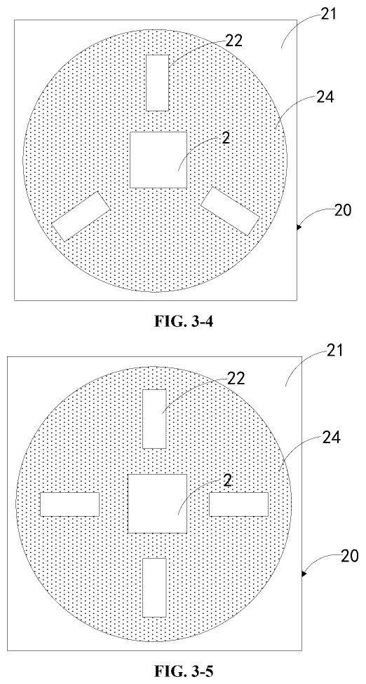

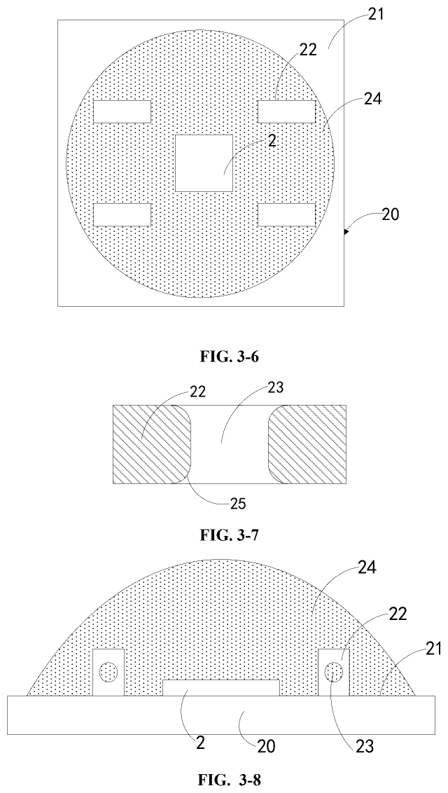

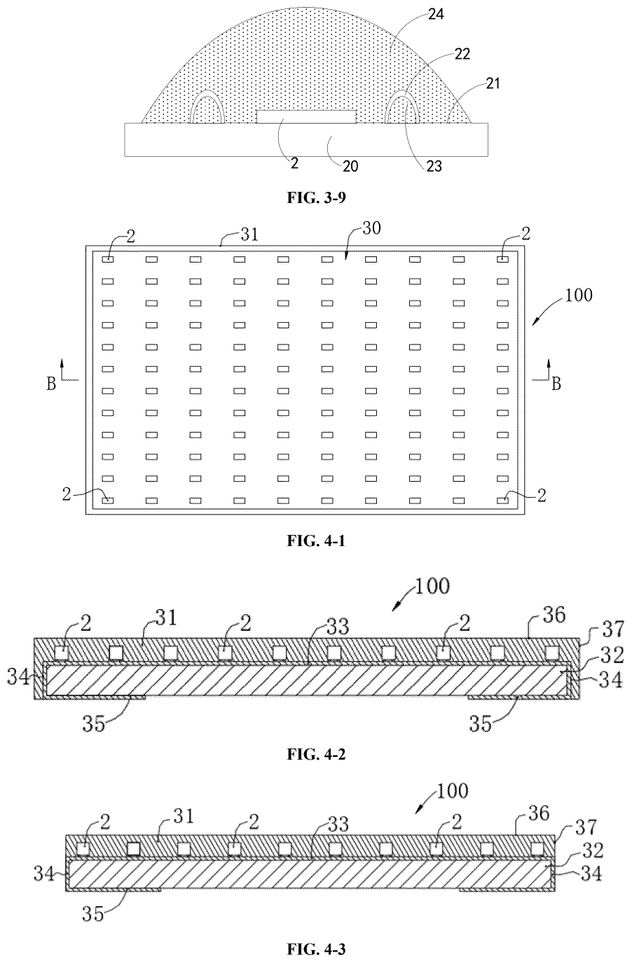

Referring to FIG. 3-1 for the display module provided in this embodiment, FIG. 3-1 illustrates a schematic side-view structure of the display module corresponding to a single set of light-emitting chips. The structure of this display module specifically includes:
a substrate 20, wherein the mounting surface 21 of the substrate 20 is provided with a first pad area corresponding to the light-emitting chip 2;
the light-emitting chip 2, which is fixed on the mounting surface 21, with its electrodes electrically connected to the corresponding second pads in the first pad area;
at least one reinforcing member 22, fixedly protruding from the mounting surface 21, with a through hole 23 penetrating both sides of the reinforcing member 22;
an encapsulation layer, which includes a second encapsulation adhesive layer 24 applied to the mounting surface 21, wrapping the light-emitting chip 2 and the reinforcing member 22, with the encapsulation material of the second encapsulation adhesive layer 24 filling and penetrating the through hole 23, and the second encapsulation adhesive layer 24 inside and outside the through hole 23 being integrally cured.

The main structure of the display module in this embodiment includes the substrate 20 as the carrier and the light-emitting chip 2 for illumination. The substrate 20 encompasses both single-sided and double-sided display substrates, and the surface of the substrate 20 where the light-emitting chip 2 is placed is referred to as the mounting surface 21.

In this embodiment, the substrate 20 can be a composite substrate formed by a multilayer structure, where each layer includes a base material layer that provides the substrate's strength and form, a circuit layer that supplies power to the various components on the substrate 20, and a solder resist layer that protects the circuit layer. The material of the base material layer can be glass, ceramic, resin, etc., and it is formed at the bottommost layer of the substrate 20. To protect the circuits on the circuit layer and enhance the light-emitting effect of the light-emitting chip 2, a solder resist layer is applied over the circuit layer. The solder resist layer serves to cover the parts of the circuit layer that do not need to be exposed, thereby reducing external influences on the circuit layer. For positions requiring external electrical connections, such as the first pad area on the circuit layer, the solder resist layer must avoid covering these areas while covering the rest of the circuit layer, meaning a window opening is created in the solder resist layer. The purpose of the window opening is to expose the corresponding pads, allowing components like the light-emitting chip 2 that need to connect to the pads to access the first pad area through the window opening, achieving electrical connection with the circuit layer. In other words, in this embodiment, the mounting surface 21 of the substrate 20 typically includes the solder resist layer and the exposed first pad area of the circuit layer.

The light-emitting chip 2 is fixedly connected to the mounting surface 21, which includes both positional and electrical connections. For flip-chip type light-emitting chips 2, this is usually achieved by directly contacting the electrodes of the light-emitting chip 2 with the first pad area or connecting them via conductive materials such as solder or silver paste, thereby simultaneously establishing positional and electrical connections. For wire bonding light-emitting chips 2, the light-emitting chip 2 is first fixed within a die-attach area, and then its electrodes are electrically connected to the first pad area via bonding wires.

To meet the requirements for adjusting the light-emitting angle of the light-emitting chip 2, modifying parameters such as the light emission type, or providing encapsulation protection for the light-emitting chip 2, a corresponding second encapsulation adhesive layer 24 is typically applied around the light-emitting chip 2. For a single group of light-emitting chips 2, the second encapsulation adhesive layer 24 completely encapsulates the group, and the methods for applying the second encapsulation adhesive layer 24 include, but are not limited to, molding, injection molding, dispensing, and other processes.

To enhance the bonding strength of the second encapsulation adhesive layer 24, particularly between the second encapsulation adhesive layer 24 and the substrate 20, in the embodiment, at least one reinforcing member 22 is fixed and protruded on the mounting surface 21. The reinforcing member 22 is provided with a through hole 23, as shown in FIG. 3-1. The purpose of arranging the reinforcing member 22 is to maintain a fixed positional relationship between the reinforcing member 22 and the mounting surface 21 based on their fixed configuration. By incorporating the through hole 23 on the reinforcing member 22, the uncured second encapsulation adhesive layer 24 (i.e., the uncured encapsulation material) can flow into and fill the through hole 23 during the application of the second encapsulation adhesive layer 24. The second encapsulation adhesive layer 24 within the through hole 23 will then connect with the layer outside the through hole 23 at both ends of the through hole 23, subsequently curing as a single unit. This creates an interlocking structure between the through hole 23 and the second encapsulation adhesive layer 24, significantly improving the bonding strength between the second encapsulation adhesive layer 24 and the substrate 20. As a result, even if the adhesive properties of the second encapsulation adhesive layer 24 are suboptimal, the interlocking mechanism prevents it from peeling off the substrate 20. To achieve this, the through hole 23 is designed to penetrate both sides of the reinforcing member 22. Specifically, the extension direction of the through hole 23 may be parallel to the mounting surface 21 or form a non-90° angle with the mounting surface 21. This ensures that the second encapsulation adhesive layer 24 filling the through hole 23 can connect with the second encapsulation adhesive layer 24 outside the through hole 23 via both openings of the through hole 23. For stability between the reinforcing member 22 and the second encapsulation adhesive layer 24, the reinforcing member 22 is typically made of a material with high rigidity.

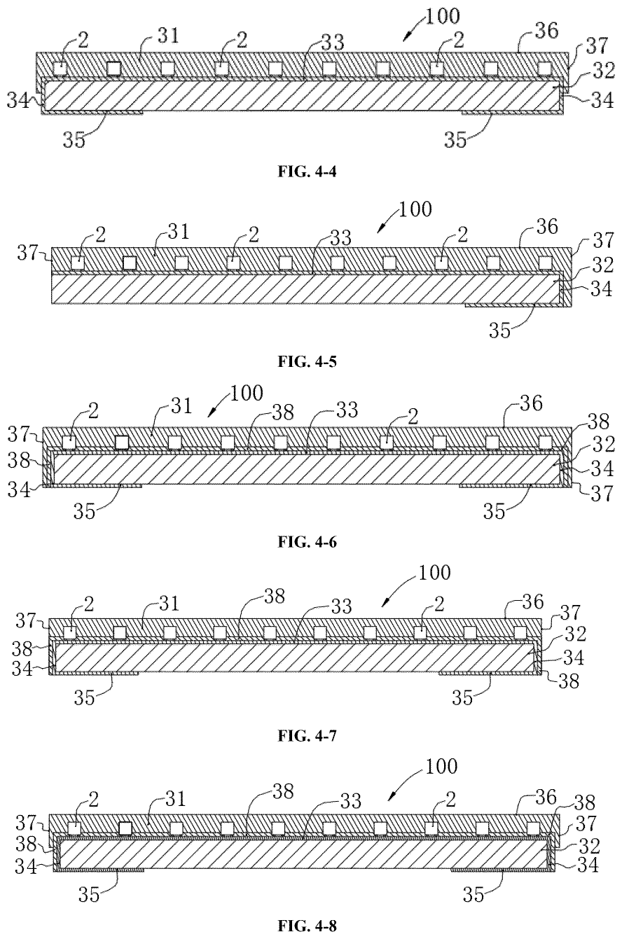

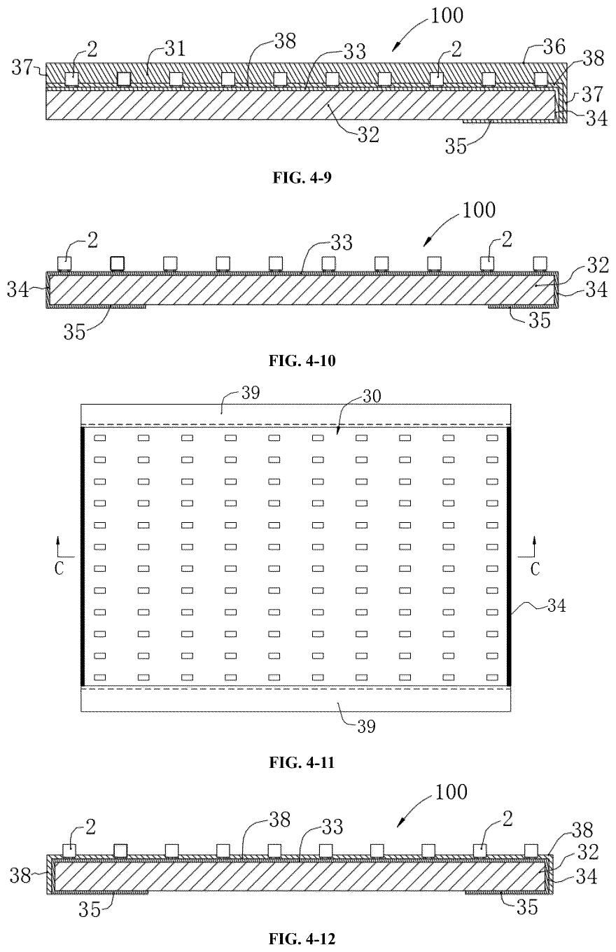

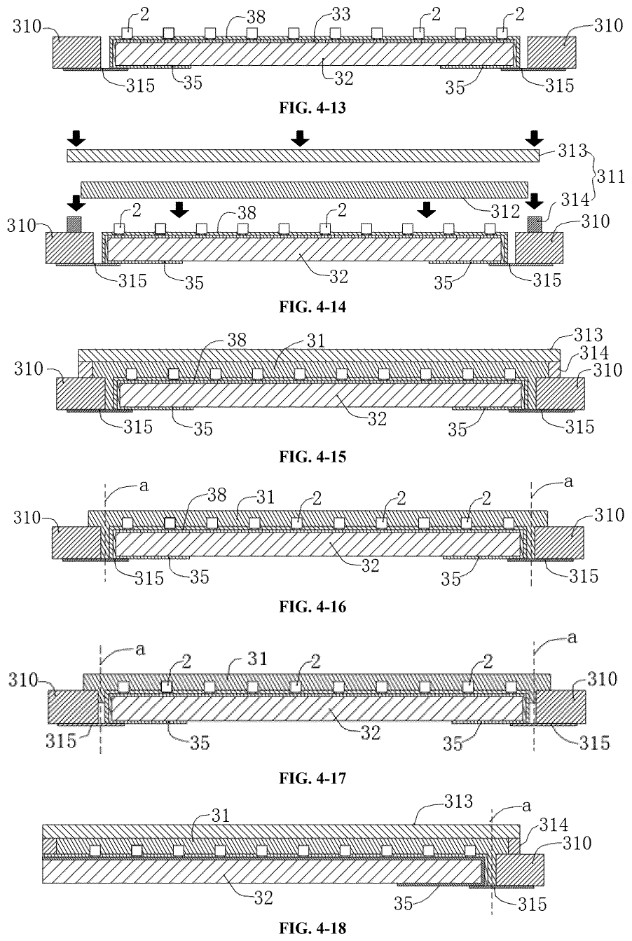

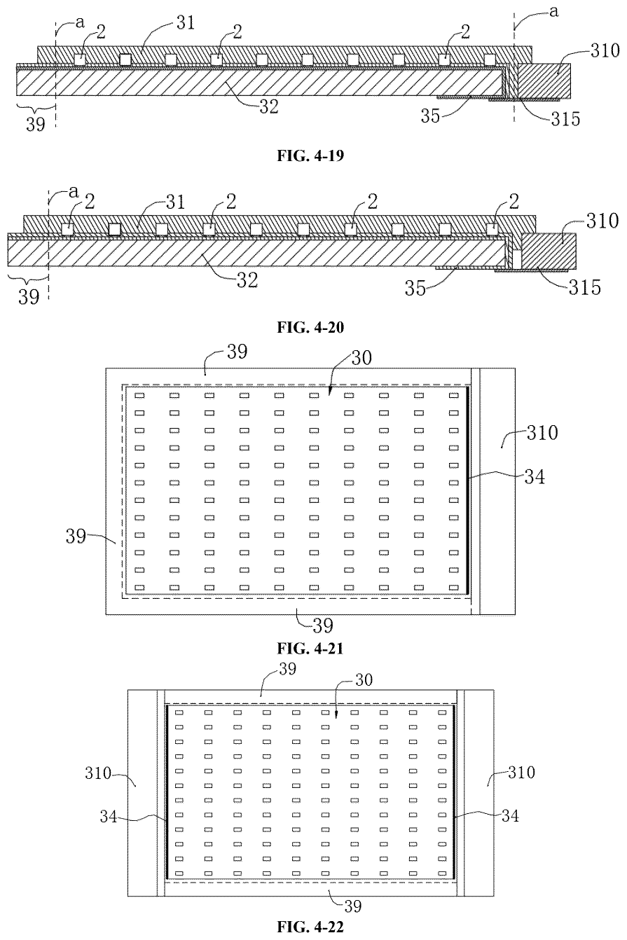

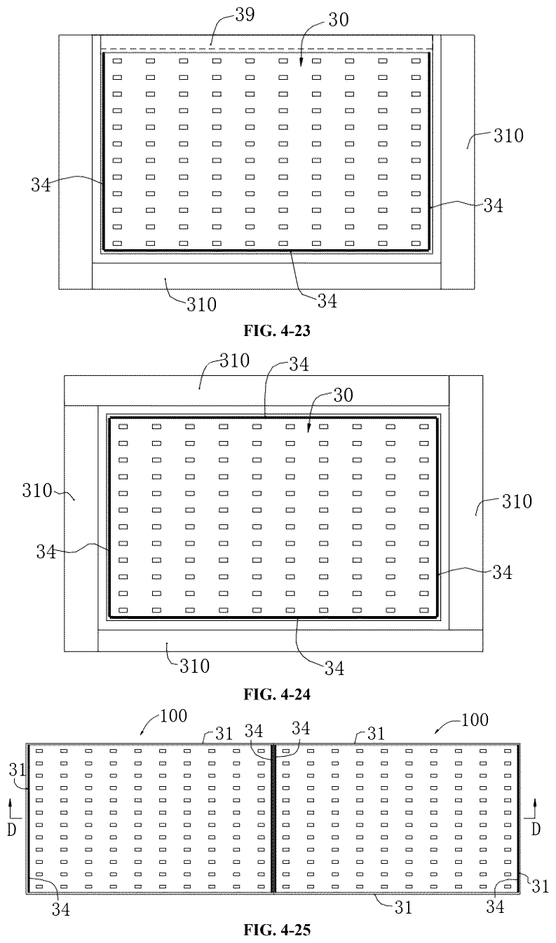

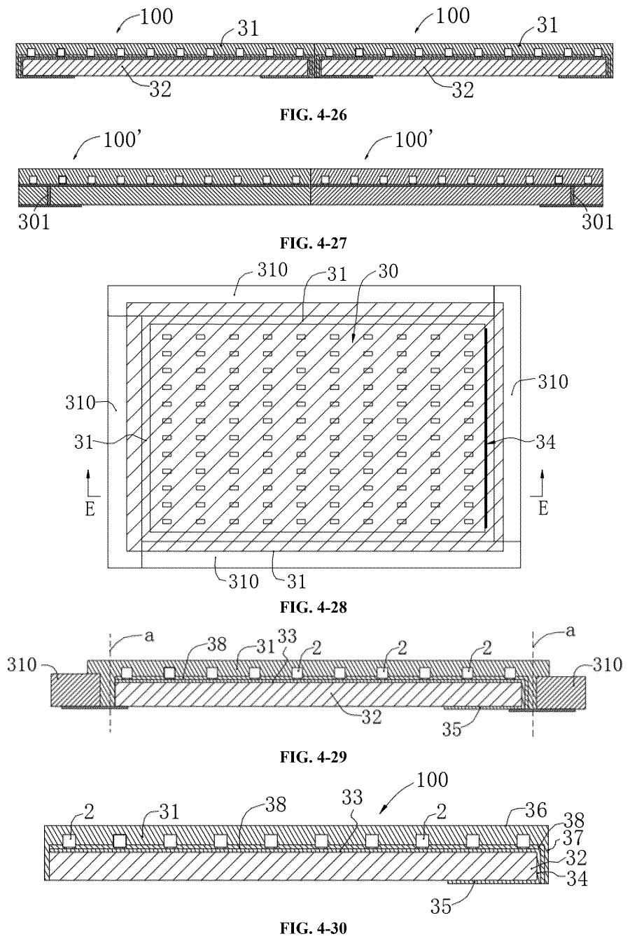

In some optional examples, to further enhance the bonding between the second encapsulation adhesive layer 24 and the substrate 20, the number of reinforcing members 22 corresponding to each first pad area can be set to greater than or equal to 2, and each reinforcing member 22 is arranged symmetrically based on the geometric center of the light-emitting chip 2. The more reinforcing members 22 are installed, the more significant the improvement in the bonding force between the second encapsulation adhesive layer 24 and the substrate 20. A plurality of reinforcing members 22 can form an arrayed interlocking structure, enhancing the bonding between the second encapsulation adhesive layer 24 and the substrate 20 across a plurality of dimensions. If the second encapsulation adhesive layer 24 is a fluorescent adhesive or similar material used to adjust the display angle or parameters of the light-emitting chip 2, then for uniformity considerations, the reinforcing members 22 are generally arranged symmetrically based on the geometric center of the light-emitting chip 2. The specific symmetry can be either central symmetry or axial symmetry, ensuring that the light emitted by the light-emitting chip 2 achieves good consistency across all angles. Typically, when the number of reinforcing members 22 is even, they are arranged in axial symmetry based on the symmetry axis of the light-emitting chip 2 or in central symmetry based on the geometric center of the light-emitting chip 2. When the number of reinforcing members 22 is odd, the reinforcing members 22 are mostly arranged in central symmetry based on the geometric center of the light-emitting chip 2, as shown in FIGS. 3-2 to 3-6. Specifically: FIG. 3-2 shows two reinforcing members 22 arranged in axial symmetry; FIG. 3-3 shows two reinforcing members 22 arranged in central symmetry; FIG. 3-4 shows three reinforcing members 22 arranged in axial symmetry; FIG. 3-5 shows four reinforcing members 22 arranged in central symmetry; and FIG. 3-6 shows four reinforcing members 22 arranged in axial symmetry.

In some optional examples, to secure the reinforcing member 22 to the mounting surface 21, the reinforcing member 22 can be integrally formed with the substrate 20; alternatively, the reinforcing member 22 can be fixed to the mounting surface 21 of the substrate 20 through methods such as adhesive bonding or soldering.

If the reinforcing member 22 and the mounting surface 21 are two separate components, the reinforcing member 22 can be fixedly connected to the mounting surface 21 using the same method as for the light-emitting chip 2. Specifically, if the reinforcing member 22 is made of a non-metallic material, die-bonding adhesive can be used to secure it. If the reinforcing member 22 is made of a metallic material, fixed connection to the mounting surface 21 can be achieved through soldering, flux eutectic bonding, or similar methods. When the reinforcing member 22 is metallic, its placement should generally avoid interfering with the first pad area to prevent affecting the circuit stability of the light-emitting chip 2.

In some optional examples, as shown in FIGS. 3-7, the reinforcing member 22 is provided with a chamfer 25 at the opening of the through hole 23. The chamfer 25 at the opening of the through hole 23 allows the second encapsulation adhesive layer 24 before curing to flow more smoothly into the through hole 23. Additionally, it increases the area of the second encapsulation adhesive layer 24 at the junction inside and outside the through hole 23, enhancing the integrated connection strength of the second encapsulation adhesive layer 24 across the through hole 23. Specifically, the chamfer 25 at the opening of the through hole 23 can be a curved or flat angle, and its size can be adjusted based on the dimensions of the through hole 23, which is not limited in this embodiment.

In some optional examples, to minimize the impact of the reinforcing member 22 on the display effect of the light-emitting chip 2, the reinforcing member 22 may be made of transparent material. Alternatively, if the reinforcing member 22 is made of opaque material, its surface can be coated with a reflective layer. If the reinforcing member is transparent, it allows light emitted by the light-emitting chip to pass through unimpeded, ensuring minimal interference with the chip's light output. If the reinforcing member is opaque, such as metal or opaque plastic, a reflective layer can be applied to its surface to reflect the light emitted by the chip, thereby enhancing the light output effect. The reflective layer can be formed by electroplating a high-reflectivity material, such as silver or aluminum, onto the surface of the reinforcing member.

In some optional examples, the shape of the through hole 23 may include at least one of a rectangle, circle, ellipse, semi-ellipse, or triangle. As shown in FIGS. 3-1, 3-8, and 3-9, the through hole 23 in FIG. 3-1 is rectangular, in FIG. 3-8 it is circular, and in FIG. 3-9 it is semi-elliptical.

In some optional examples, to enhance the integral connection strength of the second encapsulation adhesive layer 24 inside and outside the through hole 23, the cross-sectional area of the through hole 23 is greater than or equal to 50% of the cross-sectional area of the reinforcing member 22 in the corresponding direction. Under the same dimensions of the reinforcing member 22, the larger the cross-sectional area of the through hole 23, the more second encapsulation adhesive layer 24 it can accommodate, thereby increasing the connection strength of the second encapsulation adhesive layer 24. Since the material strength of the reinforcing member 22 is often higher than that of the second encapsulation adhesive layer 24, ensuring a certain strength of the reinforcing member 22 can improve the integral connection strength of the second encapsulation adhesive layer 24 inside and outside the through hole 23, further enhancing the adhesion between the second encapsulation adhesive layer 24 and the substrate 20.

In some optional examples, as shown in FIGS. 3-1 and 3-9, part of the boundary of the through hole 23 is formed by the mounting surface 21. This allows the second encapsulation adhesive layer 24 inside the through hole 23 to directly contact the mounting surface 21, meaning the second encapsulation adhesive layer 24 can directly cover the mounting surface 21, increasing the contact area between the second encapsulation adhesive layer 24 and the mounting surface 21. In this case, for the second encapsulation adhesive layer 24 with a certain viscosity, direct contact with the mounting surface 21 can also ensure the adhesion between the second encapsulation adhesive layer 24 and the substrate 20.

The display module provided in this embodiment features a reinforcing member 22 with a through hole 23 fixed on the mounting surface 21. This allows the second encapsulation adhesive layer 24 to be injected into the through hole 23 during application, and the second encapsulation adhesive layer 24 inside and outside the through hole 23 solidifies into a whole, forming an interlocking structure between the reinforcing member 22 and the second encapsulation adhesive layer 24. This significantly improves the bonding force of the second encapsulation adhesive layer 24 and reduces the risk of its detachment.

This embodiment also provides a method for manufacturing a display module, including the following steps:

S201: a substrate is provided, which includes a mounting surface, wherein the mounting surface is equipped with a first pad area corresponding to the light-emitting chip; the light-emitting chip is fixed on the mounting surface and electrically connected to the corresponding second pad in the first pad area; the provided substrate also includes a reinforcing member fixed and protruding on the mounting surface, with a through hole penetrating both sides of the reinforcing member.

In this embodiment, the substrate can be formed from three layers, including sequentially a base material layer, a circuit layer, and a solder resist layer. During the manufacturing of the display module, a base material layer is first provided, then the circuit layer is formed on the base material layer, and finally the solder resist layer is formed above the circuit layer.

The sequence of fixedly arranging the light-emitting chip and the reinforcing member on the substrate can be arbitrary in this embodiment. It may involve first fixing the reinforcing member and then installing the light-emitting chip, or first bonding the light-emitting chip and then setting the reinforcing member. Alternatively, the reinforcing member itself may be directly integrated with the substrate.

Next, an encapsulation layer covering each light-emitting chip is arranged on the substrate, which includes the following steps:

S202: an uncured encapsulation material is provided to envelop the light-emitting chips and reinforcing member, with at least part of the material filling the through holes.

The uncured encapsulation material is fluid. When applied through processes like dispensing, it naturally flows into the through hole on the reinforcing member and fills the through hole. The material entering the through hole merges with the surrounding encapsulation material, forming a closed loop around the reinforcing member.

S203: the encapsulation material is cured to form a second encapsulation adhesive layer, with the material inside and outside the through holes solidifying as one.

After curing the uncured encapsulation material, the second encapsulation adhesive layer is formed, losing its fluidity and gaining strength and hardness. The second encapsulation adhesive layer includes a closed loop interlocking with the reinforcing member's through holes, significantly enhancing adhesion between the second encapsulation adhesive layer and the substrate and reducing the risk of detachment of the second encapsulation adhesive layer.

### Embodiment 3

In related technologies, COG (Chip On Glass) display modules use glass substrates, which offer the advantages of high flatness and low thermal expansion (i.e., low coefficient of thermal expansion), enabling smaller LED chip spacing and making them ideal for Mini LED chip bonding and high-resolution displays. The display modules can be tiled to form large screens. Existing COG modules feature circuits on both the front and back of the glass substrate: front circuits connect to Mini LED electrodes, while back circuits link to external wiring. As shown in FIG. 4-27, a conventional display module 100′ uses through holes 301 filled with a conductive material to connect front and back circuits, reducing pixel gaps at joints during tiling large screens. However, configuration of through holes in the glass substrate will weaken the glass substrate's strength.

To address these issues, this embodiment provides a novel display module. It should be noted that this module can be implemented independently or combined with other embodiments where no conflicts arise. For clarity, the following illustrates this display module.

As shown in FIGS. 4-1 to 4-2, this embodiment provides a display module 100 suitable for tiling. The display module 100 includes a substrate 30, a plurality of light-emitting chips 2, and a third encapsulation adhesive layer 31. The substrate 30 includes an insulating second insulating base layer 32, which has oppositely arranged first and second surfaces, as well as a plurality of sides connecting the first and second surfaces. In this embodiment, the second insulating base layer 32 is square, with four sides between the first and second surfaces. The first surface of the second insulating base layer 32 is provided with a second circuit layer 33, while the second surface is provided with a third circuit layer 35. At least one side of the second insulating base layer 32 is provided with a side circuit layer 34, which connects at least part of the second circuit layer 33 and the third circuit layer 35, enabling conduction between at least some circuits of the second circuit layer 33 and the third circuit layer 35. The plurality of light-emitting chips 2 are mounted on the second circuit layer 33 and conduct with external circuits sequentially through the side circuit layer 34 and the third circuit layer 35. The material of the second insulating base layer 32 is preferably glass, which offers high flatness and low thermal expansion, making it suitable for arranging light-emitting chips at small pitches without compromising optical performance due to environmental temperature or humidity changes. In this embodiment, the side circuit layer 34 is arranged on the side surface of the substrate 30 to electrically connect the second circuit layer 33 and the third circuit layer 35. Compared with conventional techniques where through holes are drilled in the substrate to connect circuits on both sides of the substrate, this embodiment eliminates the need for drilling holes in the substrate 30, thereby achieving higher overall structural strength.

The light-emitting chip 2 in the aforementioned display module 100 can be a Mini LED chip, Micro LED chip, or LED package, and may include but is not limited to flip-chip Mini LED chips. A plurality of Mini LED chips can be any of red-light Mini LED chips, green-light Mini LED chips, or blue-light Mini LED chips, or a combination thereof. The third encapsulation adhesive layer 31 is fixed to the substrate 30 and covers the second circuit layer 33 on the first surface of the second insulating base layer 32, the light-emitting chip 2, and at least part of the side circuit layer 34. The third encapsulation adhesive layer 31 can be epoxy or silicone resin and has an upper surface 36 that is exposed on the display module 100 and orthogonal to the extended plane of the side of the substrate 30. The display module 100 features a splicing side for connecting with adjacent display modules 100. The third encapsulation adhesive layer 31 has a side surface 37 connected to the upper surface 36, forming at least part of the splicing side, and this side surface 37 of the third encapsulation adhesive layer 31 is flat. At the splicing side, the side surface 37 and upper surface 36 of the third encapsulation adhesive layer are connected at a right angle, which can be understood as 90 degrees or approximately 90 degrees, as long as it does not affect the splicing effect. In this embodiment, by configuring the side surface 37 of the third encapsulation adhesive layer 31 on the splicing side of the display module 100 to connect with the adjacent upper surface 36 at a right angle, when adjacent display modules 100 are spliced together through the splicing side, only the upper surface of the third encapsulation adhesive layer 31 is exposed at the splicing location on the resulting display screen. After splicing, only the upper surface of the third encapsulation adhesive layer 31 serves as the light-emitting surface of the LED display at the splicing location, with no rounded or beveled edges, ensuring uniform light emission near and far from the splicing location. This enhances the optical quality of the LED display, achieving a near-zero-seam splicing effect.

In some optional examples, the thicknesses of the second circuit layer 33, third circuit layer 35, and side circuit layer 34 are the same, such as 1 μm to 6 μm thick, preferably 2 μm to 3 μm. In practical applications, the thickness of the second circuit layer 33 and third circuit layer 35 should not exceed 6 μm, as it may cause slight deformation of the second insulating base layer 32. In other examples, the thicknesses of the second circuit layer 33, third circuit layer 35, and side circuit layer 34 can differ. For instance, the side circuit layer 34 may be thicker than the second circuit layer 33. Since the side circuit layer 34 may be exposed on the side of the display module 100, its thickness being greater than that of the second circuit layer helps enhance its mechanical strength and improve reliability.

In some optional examples, the second circuit layer 33, the third circuit layer 35, and the side circuit layer 34 are metal layers formed through coating processes such as magnetron sputtering or thermal evaporation, tightly adhering to the second insulating base layer.

In this embodiment, the function of the third circuit layer 35 is to provide a circuit interface for connecting the display module to external circuits. Therefore, in this embodiment, the third circuit layer 35 only needs to partially cover the second surface (i.e., the back side) of the second insulating base layer 32. In other examples, the third circuit layer 35 can also be expanded for more uses, such as connecting with other electronic components. Depending on design requirements, the third circuit layer 35 can cover the entire second surface of the second insulating base layer 32. This application does not limit the area, size, or form of the third circuit layer 35. However, in any case, the third circuit layer 35 must be arranged on the second surface of the second insulating base layer 32.

Since the side circuit layer 34 has a certain thickness, at least part of it will be exposed on the first surface of the second insulating base layer 32. Therefore, the third encapsulation adhesive layer 31 will cover at least part of the side circuit layer 34 (i.e., the third encapsulation adhesive layer 31 will at least come into contact with a portion of the side circuit layer). As shown in FIG. 4-3, the third encapsulation adhesive layer 31 covers the top of the side circuit layer 34, while the side of the side circuit layer 34 is exposed on the side of the display module 100. As shown in FIG. 4-4, the third encapsulation adhesive layer 31 covers the top and part of the side of the side circuit layer 34, with part of the side of the side circuit layer 34 exposed on the side of the display module 100.

In this embodiment, the function of the side circuit layer 34 is to connect the second circuit layer 33 and the third circuit layer 35. The number of side circuit layers 34 can be determined based on circuit design requirements. For example, as shown in FIGS. 4-5 and 4-9, the side circuit layer 34 can be arranged only on one side of the second insulating base layer 32. Alternatively, as shown in FIGS. 4-2, 4-3, 4-4, 4-6, 4-7, and 4-8, the side circuit layer 34 can also be arranged on two opposite sides. Additionally, the side circuit layer 34 can be arranged on three or four sides.

Some optional examples, as shown in FIGS. 4-6, 4-7, 4-8, and 4-9, illustrate that the second circuit layer 33 and the side circuit layer 34 of the display module 100 are covered by a circuit protection layer 38. This circuit protection layer 38 can be an ink layer, with a thickness ranging from 5 μm to 30 μm, preferably 10 μm to 24 μm. In this embodiment, the ink layer is preferably a black ink layer. If the display module 100 is used for a screen that directly displays information, the black ink layer can enhance the contrast of the display screen. In other embodiments, the display module 100 can also be used for transparent displays. To achieve transparency, the ink layer can be a transparent or semi-transparent ink layer, or no ink layer may be applied.

Referring to FIGS. 4-7 and 4-8, in some instances, since the circuit protection layer 38 covers the side circuit layer 34, a portion of the circuit protection layer 38 may be exposed on the side of the display module in certain manufacturing processes. The splicing side can be composed of the side of the circuit protection layer 38 and the side of the third encapsulation adhesive layer 31.

As shown in FIGS. 4-6 and 4-9, some optional examples demonstrate that the third encapsulation adhesive layer 31 fully covers the side circuit layer 34, protecting both the side circuit layer 34 and the circuit protection layer 38 on it to reduce wear. The side of the display module 100 with the side circuit layer is solely formed by the side of the third encapsulation adhesive layer 31 (i.e., the third encapsulation adhesive layer covers the circuit protection layer). The third encapsulation adhesive layer 31 extends to the backside of the substrate 30 (i.e., the second surface, opposite to the side where the light-emitting chip is placed) and aligns with the substrate's backside. This design positions the boundary between the circuit protection layer 38 and the third encapsulation adhesive layer 31 at the bottom of the display module 100 (i.e., the part corresponding to the second surface). In product design, increasing the substrate thickness can extend the path for moisture to penetrate into the interior of the display module 100.

In some optional examples, the display module can be one used for directly displaying images or text information. The display module employs small-sized LED light-emitting devices, such as Mini LED chips or Micro LED chips, hence it may also be referred to as a Mini display module or Micro display module. In a Mini display module, when small-sized LED light-emitting chips are arranged in an array, they can be spaced closely to achieve high resolution for the display module. However, due to cost considerations and limitations in current production capabilities, when manufacturing some large-sized Mini LED displays, a plurality of display modules are typically spliced together to form a large-sized Mini LED display. During the production of the display module, the light-emitting chips are first fixed onto the substrate, followed by covering the light-emitting chips and substrate with a third encapsulation adhesive layer. During the application of the third encapsulation adhesive layer, a mold forming process can be used to shape the layer. When employing the mold process, it is necessary to reserve a process edge around the substrate to support the mold. After forming the third encapsulation adhesive layer with the mold, the excess process edge is trimmed off (hence the process edge may also be called a trimming edge, temporary edge, or mold support edge), reducing the edge width of the display module (i.e., the distance from the light-emitting chip closest to the edge on the substrate to the edge itself), ensuring consistent pixel spacing during splicing. For better understanding, please refer to the Chinese invention patent application with the filing date of 2021 Nov. 9, patent number CN202111166118.8, and publication date of 2022 Apr. 15. However, the display module provided in Embodiment 1 of this application must have the side circuit layer set during the substrate fabrication before forming the third encapsulation adhesive layer; it cannot form the third encapsulation adhesive layer first and then create the side circuit layer. Additionally, the side circuit layer can only be set after trimming the process edge, which results in the side where the side circuit layer is located lacking a process edge, making it impossible to use the mold to form the third encapsulation adhesive layer.

To address the above issues, this embodiment also provides a manufacturing method for the display module 100 (see FIGS. 4-10 to 4-24), which can be used to produce the aforementioned display module 100. The manufacturing method includes the following steps:

S301: (Refer to FIGS. 4-10 and 4-11) a flat substrate 30 is provided, which includes an insulating second insulating base layer 32; the second insulating base layer 32 has opposing first and second surfaces, as well as a plurality of sides connecting the first and second surfaces; the material of the second insulating base layer 32 is preferably glass, which offers high flatness and low thermal expansion, making it suitable for arranging light-emitting chips at small pitches without compromising overall optical performance due to environmental temperature or humidity changes. A second circuit layer 33 is formed on the first surface of the second insulating base layer 32, and a third circuit layer 35 is formed on its second surface. The process edges at the sides of the substrate 30 where the side circuit layer 34 is to be formed must be removed, exposing the side of the second insulating base layer and forming the side circuit layer 34 at the side of the second insulating base layer; the side circuit layer 34 is arranged on at least one side of the second insulating base layer 32 (FIG. 4-10 shows two side circuit layers). The side circuit layer 34 enables electrical conduction between at least part of the second circuit layer 33 and the third circuit layer 35.

It should be noted that the portions of the substrate 30 edges without the side circuit layer may retain the process edge 39 (see FIG. 4-11) or have it removed (i.e., cut off), which is not limited in this embodiment.

The second circuit layer 33, side circuit layer 34, and third circuit layer 35 are all formed on the second insulating base layer 32, specifically through coating processes such as magnetron sputtering or thermal evaporation. The second circuit layer 33 includes a plurality of third pads corresponding to the electrodes of the light-emitting chips 2.

In this embodiment, the side circuit layer 34 enables partial electrical conduction between the second circuit layer 33 and the third circuit layer 35. Compared to conventional techniques that use through holes in glass substrates to connect circuits on both sides of the substrate, this design offers higher substrate strength.

S302: (Refer to FIGS. 4-10 and 4-11) the light-emitting chips are arranged on the second circuit layer. A plurality of light-emitting chips 2 are provided, where the second circuit layer 33 includes third pads corresponding to the electrodes of the plurality of light-emitting chips 2. The light-emitting chips 2 are fixed onto the second circuit layer 33 of the substrate 30 via soldering or conductive adhesive bonding.

S303: after completing S301 or S302, refer to FIGS. 4-12, 4-21, 4-22, 4-23, and 4-24, a carrier board 310 (which can also be referred to as an extended process edge or auxiliary process edge) is placed on the side of the substrate 30 where the process edge is missing (including the side with the side circuit layer 34); a gap exists between the side surface of the carrier board 310 and the side surface of the substrate (i.e., a gap also exists between the side surface of the carrier board 310 and the side circuit layer 34). The carrier board 310 is preferably flat in shape. When viewed along the direction projecting toward the side of the substrate, the length of the side of the carrier board is greater than that of the side of the substrate. This embodiment does not limit the relationship between the height of the side of the carrier board and the side of the substrate, but it is preferable that the height of the side of the carrier board carrier board 310 does not exceed that of the side of the substrate surface to save material costs for the carrier board 310.

S304: refer to FIGS. 4-14, 4-15, 4-16, 4-18, and 4-19, a mold 311 and a semi-solid encapsulation adhesive film 312 (as shown in FIG. 4-14) are provided, and a mold 311 is placed on the substrate 30 (e.g., refer to the substrate 30 shown in FIG. 4-11) and the carrier board 310, ensuring that at least part of the mold 311 abuts against the carrier board 310; the semi-solid encapsulation adhesive film 312 is placed in the mold and vacuum hot pressing is performed to melt the film to cover the first surface of the substrate 30, the light-emitting chips 2, and at least part of the carrier board 310 to form the third encapsulation adhesive layer, with the upper surface of the third encapsulation adhesive layer being orthogonal to the extended plane of the side of the substrate surface; curing is performed to obtain a cured third encapsulation adhesive layer.

In some embodiments, the third encapsulation adhesive layer may be a thermosetting epoxy or silicone resin.

In some optional examples, the mold includes a pressure plate 313 and spacer blocks 314. The spacer blocks 314 are placed on the process edge and/or the carrier board, cooperating with the pressure plate 313 to form a mold cavity. The semi-solid encapsulation adhesive film 312 is placed in the cavity. The pressure plate 313 is pressed down and heated to melt the semi-solid encapsulation adhesive film 312, filling the cavity and covering the light-emitting chips.

S305: refer to FIGS. 4-16, 4-17, and 4-19, a cutting tool is used to remove the carrier board 310, the encapsulant attached to the carrier board 310, and the excess process edge 39 along the gap between the side of the substrate surface and the carrier board 310 parallel to the side of the substrate surface (i.e., along the dashed line “a” in FIGS. 4-16, 4-17, 4-18, and 4-19), resulting in the display module 100 (as shown in FIGS. 4-1, 4-6, 4-8, and 4-9). This display module 100 has a splicing side, which includes the side surface of the third encapsulation adhesive layer.

Since the carrier board 310 is typically harder than the third encapsulation adhesive layer to stably support the mold, cutting along the gap between the side surface of the carrier board 310 and the side surface of the substrate 30 ensures that only the third encapsulation adhesive layer is cut, avoiding damage to the carrier board 310. This improves the usage count of the cutting tool and enhances cutting efficiency.

In this embodiment, by arranging the second circuit layer 33, side circuit layer 34, and third circuit layer 35 on the second insulating base layer 32 made of glass, and connecting the second circuit layer 33 and third circuit layer 35 through the side circuit layer 34, the strength of the glass substrate is preserved without the need for through holes. When forming the third encapsulation adhesive layer using the mold, the auxiliary carrier board 310 allows the mold to abut against the carrier board 310. After injecting adhesive into the mold cavity and performing vacuum hot pressing, the encapsulant covers the first surface of the substrate 30, the light-emitting chips 2, and the carrier board 310. The upper surface of the encapsulant is orthogonal to the extended plane of the side of the substrate surface. By cutting along the gap between the side surface of the substrate 30 and the carrier board 310 parallel to the side of the substrate surface, the carrier board 310 and the encapsulant attached to the carrier board 310 are removed, revealing the splicing side of the display module 100. This splicing side includes the remaining encapsulant after cutting, i.e., the side surface of the third encapsulation adhesive layer 31. The cutting process removes the encapsulant formed above the carrier board 310, enabling a right-angle connection between the side surface of the third encapsulation adhesive layer 31 and the upper surface of the third encapsulation adhesive layer 31 adjacent to the side surface. When two display modules 100 are spliced together via their splicing sides to form a display screen, the splicing sides achieve tight adhesion through the right-angle edges. In the assembled display screen, only the upper surface of the third encapsulation adhesive layer 31 is exposed as the light-emitting surface, ensuring minimal differences in light output near and far from the splicing seam. This enhances the optical quality of the display screen, improves its overall coherence, and achieves a near-zero seam effect.

In some optional examples, in S302, the carrier board 310 is fixed to at least one side of the substrate 30. During fixation, the carrier board 310 and substrate 30 can be arranged at a certain spacing and connected using adhesive materials such as tape 315 to secure them. The tape 315 prevents the melted third encapsulation adhesive layer 31 from overflowing from the gap between the substrate 30 and the carrier board 310 onto the workbench or the back of the substrate 30 during the thermal pressing of the third encapsulation adhesive layer 31, which could cause the substrate 30 to adhere to the workbench and become difficult to separate. In S305, the excess process edge and carrier board 310 can be cut first before removing the tape 315; alternatively, the tape 315 can be removed first before cutting the excess process edge and carrier board 310.

In some optional examples, as shown in FIG. 4-17, there is a gap between the carrier board 310 and the substrate 30. During the pressing of the third encapsulation adhesive layer, due to its viscosity and surface tension, if the gap is too small, the third encapsulation adhesive layer 31 may not fully fill the gap, leaving space between the carrier board 310 and the substrate 30. After cutting the excess process edge and carrier board 310, the display module shown in FIG. 4-8 can be obtained.

In some optional examples, since the substrate 30 typically includes a process edge 39 during fabrication, when components on the substrate 30 are close to the edge of the substrate 30, the process edge 39 of the substrate 30 can prevent damage to the substrate 30 or the components mounted thereon during processing. As shown in FIGS. 4-21 to 4-23, when fabricating the side circuit layer 34 on the substrate 30, only the process edge 39 corresponding to the side where the side circuit layer 34 is to be fabricated needs to be cut. The remaining process edge 39 after cutting can serve as a positioning reference for the carrier board 310 during fixation of the carrier board 310, ensuring that the combined outline of the carrier board 310 and substrate 30 forms a nearly complete square to support the mold. During S304, when thermally pressing the third encapsulation adhesive layer, the mold can simultaneously abut against the process edge 39 and the carrier board 310. After thermal pressing of the third encapsulation adhesive layer, part of the remaining process edge 39 and carrier board 310 can be cut. In this example, since the process edge 39 and substrate 30 are integrated, jointly supporting the mold with the process edge 39 and the carrier board 310 enhances the mold's stability during thermal pressing, thereby improving the quality of the final product.

Specifically, in this embodiment, in S302, fixing the carrier board 310 to at least one side of the flat substrate 30 can be done on one side (see FIG. 4-21), two sides (see FIG. 4-22), or three sides (see FIG. 4-23) of the substrate 30, depending on the number of side circuit layers 34 set on the substrate 30. As shown in FIG. 4-24, the process edges 39 of the substrate may also be entirely removed, with side circuit layers 34 set on all four sides of the substrate. During the hot pressing of the third encapsulation adhesive layer 31, carrier boards 310 can be placed on all four sides. That is, in S301, none of the substrate's edges need to retain process edges. In other embodiments, even if some sides of the substrate lack side circuit layers 34, the process edges here can still be either removed or retained. If the process edge is removed, the side of the second insulating base layer 32 is exposed, and the need for side circuit layers 34 can be determined based on circuit design requirements.

In some optional examples, as shown in FIG. 4-12, S301 also includes setting a circuit protection layer 38 on the second circuit layer 33 and the side circuit layer 34. This circuit protection layer 38 can be an ink layer.

In some optional examples, the carrier board 310 can be a glass plate, stainless steel plate, copper plate, wooden board, or resin board. The material of the carrier board 310 may also be the same as that of the third encapsulation adhesive layer 31.

The method for manufacturing the display module 100 provided in this embodiment involves first removing the process edges from the substrate's edges where side circuit layers 34 are to be formed, facilitating the creation of side circuit layers. During the formation of the third encapsulation adhesive layer 31, the carrier board 310 can be placed on the edges of the substrate 30 where process edges are missing (i.e., edges with side circuit layers 34). By leveraging the carrier board 310's support to bear the mold, the third encapsulation adhesive layer 31 can be fabricated using the mold.

In another example of this embodiment, as shown in FIGS. 4-28 (where the shaded area represents the third encapsulation adhesive layer 31) and 4-29, it is evident from the above example that even if some edges of the substrate 30 do not have side circuit layers 34, the corresponding process edges can still be removed, meaning all process edges of the substrate 30 can be excised.

This example provides another method for manufacturing a display module, comprising the following steps:

S401: a substrate is provided, which includes a second insulating base layer made of a glass material; a second circuit layer is arranged on the first surface of the second insulating base layer, and a third circuit layer is arranged on the second surface opposite to the first surface of the second insulating base layer; the second circuit layer is provided with a plurality of third pads corresponding to the electrodes of the light-emitting chip; wherein the process edges at all edges of the substrate are removed, exposing the side of the second insulating base layer, and a side circuit layer is arranged on at least part of the side of the second insulating base layer, enabling electrical conduction of at least part of the circuits between the second circuit layer and the third circuit layer.

S402: light-emitting chips are placed on the plurality of third pads of the second circuit layer.

S403: carrier boards on are installed the side edges of the substrate, with a gap existing between the side of the carrier board and the side of the substrate.

S404: a mold and a semi-solid encapsulation adhesive film are provided, and a mold is placed on the substrate and carrier board, ensuring at least part of the mold presses against the carrier board; the semi-solid encapsulation adhesive film is placed in the mold and vacuum hot pressing is performed, causing the semi-solid encapsulation adhesive film to melt and cover the first surface of the substrate, the light-emitting chips, at least part of the carrier board, and at least part of the gap between the substrate and the carrier board, forming a third encapsulation adhesive layer, with the upper surface of the third encapsulation adhesive layer being orthogonal to the extended plane of the side of the substrate; curing is performed to obtain a cured third encapsulation adhesive layer.

S405: a cutting tool is used to remove the carrier board and the third encapsulation adhesive layer attached to the carrier board along the gap between the side of the substrate and the carrier board, parallel to the side of the substrate, to obtain the display module. Refer to FIG. 4-29, where the excess third encapsulation adhesive layer and carrier board 310 are cut along the dotted line a to obtain the display module shown in FIG. 4-30.

The advantage of this method is that when forming the third encapsulation adhesive layer, regardless of whether the substrate edges have a side circuit layer, the third encapsulation adhesive layer can at least partially fill the gap between the substrate and the carrier board, thereby wrapping around the substrate and providing comprehensive protection for the side edges of the substrate. This ensures good airtightness between the substrate and the third encapsulation adhesive layer, preventing moisture from invading the light-emitting device. Additionally, in S405, when removing the excess carrier board 310 and third encapsulation adhesive layer 31, the cutting tool only cuts through the third encapsulation adhesive layer, which is soft and easy to cut, avoiding simultaneous cutting of the harder substrate 30 and the softer third encapsulation adhesive layer 31. This prevents gaps caused by differing stress from the cutting tool on the substrate 30 and the third encapsulation adhesive layer 31 during cutting.

Referring to the example in FIG. 4-30, the display module only has a side circuit layer on one edge of the substrate, while the other edges are covered by the third encapsulation adhesive layer 31, which protects the side of the substrates. Moreover, the path for moisture to reach the light-emitting chip 2 is long, and the side of the substrates exhibit excellent airtightness with the third encapsulation adhesive layer 31.

In another example of this embodiment, as shown in FIGS. 4-25 to 4-26, an LED display screen is provided, formed by splicing the display module 100 described in the above example. The display modules 100 are connected via connectors (not illustrated), and then the connectors are tightly secured to the structural frame using copper pillars (which can also be replaced with connecting pillars of other materials), resulting in an LED display with minimal splicing gaps. The spliced LED display provided in this embodiment demonstrates consistent optical visual effects near and away from the splicing gaps, achieving a near-zero-gap display effect.

### Embodiment 4

In related technologies, a display module based on a glass substrate requires a layer of white ink to be coated on the glass substrate through a printing process. The white ink layer cannot be too thin, otherwise the reflectivity will be significantly reduced. The ink layer typically has a thickness of 20 μm to 50 μm, and the ink above the pads where LED chips are placed is removed to expose the pads (this can be referred to as window opening, with the area where the ink layer is removed being the window). To facilitate the subsequent printing of solder paste on the pads, the ink between the pads is also removed during the window opening process. The purpose of coating white ink is to improve the reflectivity of the glass substrate, but the window opening treatment of the white ink causes the light emitted by the LED chips to pass through the window and the glass substrate, greatly affecting the light efficiency of the backlight panel. If the window opening is too large, the light emitted by the LED chips will be lost through the glass. Due to the small size of the LED chip's welding electrodes and the certain thickness of the ink layer, if the window opening is too small, the stencil for printing solder paste will be mostly supported and lifted by the white ink during solder paste printing, resulting in inadequate contact between the stencil apertures corresponding to solder pads and the pads on the printed circuit board, thus reducing consistency in solder paste volume and positional accuracy across the pads during solder paste printing, potentially causing poor die bonding. Therefore, the window opening cannot be too large or too small. However, in existing technologies, the window opening area must be larger than the base area of the LED chip, preventing the white ink from fully covering the glass substrate surface, as the window opening always exposes the glass substrate surface. Meanwhile, the light efficiency of the display module has always been limited by the reflectivity of the white ink. Thus, how to overcome the aforementioned technical issues and defects has become a key problem to address.

To address the above issues, this embodiment provides a novel display module. It should be understood that the display module in this embodiment can be implemented independently of other embodiments and, where no conflict exists, can be combined with other embodiments. For ease of understanding, the following provides an exemplary description of this display module.

As shown in FIGS. 5-1 to 5-2, the substrate of the display module provided in this embodiment includes a third insulating base layer 41, a fourth circuit layer 42, and a first reflective film layer 43, as well as a metal plating layer 45 and a light-emitting chip 2. The surface of the third insulating base layer 41 is provided with the fourth circuit layer 42. The fourth circuit layer 42 includes at least two oppositely spaced and non-contacting second pad areas 44 for soldering the light-emitting chip 2. The second pad areas 44 are plated with the metal plating layer 45. The spaced interval between the at least two oppositely arranged second pad areas 44 forms a recess 46 with the surface of the third insulating base layer 41. The first reflective film layer 43 is disposed both above the fourth circuit layer 42 and on the third insulating base layer 41 within the recess 46. The thickness of the first reflective film layer 43 is less than 10 μm. The upper end of the metal plating layer 45 is exposed from the first reflective film layer 43 to serve as a fourth pad. The light-emitting chip 2 is mounted on the metal plating layer 45, with its bottom surface positioned higher than the first reflective film layer 43.

A method for manufacturing an optional example of the display module includes: depositing a metal layer on the third insulating base layer 41, then preparing the fourth circuit layer 42 through processes such as evaporation, exposure, and etching; next, forming the first reflective film layer 43 on both the surface of the fourth circuit layer 42 and the third insulating base layer 41 within the recess, wherein the first reflective film layer 43 fully covers the fourth circuit layer 42; subsequently, processing the portions of the first reflective film layer 43 corresponding to the second pad areas (the second pad areas are two ends positioned closely but spaced apart on the fourth circuit layer 42 for connecting the light-emitting chip) via exposure and etching to expose the second pad areas 44 on the fourth circuit layer 42, thereby creating the second pad areas 44 on the fourth circuit layer 42; then electroplating the metal plating layer 45 onto the second pad areas 44, and connecting the light-emitting chip 2 to the metal plating layer 45, wherein the light-emitting chip 2 can be soldered with the metal plating layer 45 using the using solder paste.

From the above structure, it can be seen that, except for the second pad areas, the third insulating base layer 41 is entirely covered by the first reflective film layer 43. This ensures that the first reflective film layer 43 is adjacent to the second pad areas 45, blocking light transmission through the third insulating base layer and thereby improving light efficiency.

Optionally, the thickness of the first reflective film layer 43 is less than 3 μm. Compared to the prior art, which uses an ink layer to enhance reflectivity, where the ink layer typically ranges from 20 μm to 50 μm in thickness, the excessive thickness of the ink layer can affect the die-bonding yield. In this embodiment, the first reflective film layer 43 has a thickness of less than 3 μm, making it easy for the stencil to print solder paste on the second pad area 43, thereby improving the die-bonding yield.

Optionally, in this embodiment, the first reflective film layer 43 is closely adjacent to the fourth pad, effectively avoiding the optical loss caused by excessively large window openings in the ink layer of existing solutions and significantly enhancing the light efficiency of the lamp board.

As shown in FIGS. 5-1 to 5-2, in this embodiment, the fourth circuit layer 42 is selected from at least one of a single Cu (copper) circuit layer, a single Ti (titanium) circuit layer, a single Al (aluminum) circuit layer, or a single Mo (molybdenum) circuit layer.

In one example, the fabrication method of the fourth circuit layer 42 includes depositing a metal layer on the third insulating base layer 41. The metal layer is one of a Cu layer, Ti layer, Al layer, Ti layer, or Mo layer, with a thickness ranging from 400 nm to 6000 nm. The metal layer undergoes processes such as evaporation, exposure, and etching to form the fourth circuit layer 42.

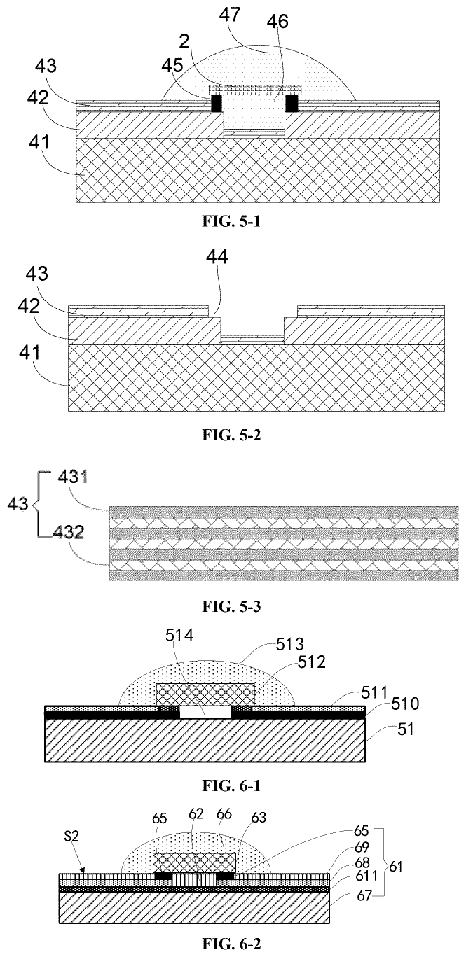

As shown in FIG. 5-3, in this embodiment, the first reflective film layer 43 includes a first reflective film sublayer 431 and a second reflective film sublayer 432 with different reflectivities. The first reflective film layer 43 is formed by alternately stacking the first reflective film sublayer 431 and the second reflective film sublayer 432. This structure gives the first reflective film layer 43 a high reflectivity.

Optionally, the thickness of the first reflective film sublayer 431 ranges from 100 nm to 500 nm, and the thickness of the second reflective film sublayer 432 ranges from 200 nm to 1000 nm. The number of alternating stacks of the first reflective film sublayer 431 and the second reflective film sublayer 432 is between 3 and 21 layers. This ensures that the first reflective film layer 43 has high reflectivity for light in the wavelength range of 400 nm to 490 nm, with an average reflectivity ≥99.5%.

As shown in FIG. 5-3, in this embodiment, the refractive index of the first reflective film sublayer 431 is higher than that of the second reflective film sublayer 432.

As shown in FIG. 5-3, in this embodiment, the first reflective film sublayer 431 is selected from one or two of TiO₂ film, ZrO₂ film, HfO₂ film, and Ta₂O₅ film.

As shown in FIG. 5-3, in this embodiment, the second reflective film sublayer 432 is selected from SiO₂ film.

Optionally, by increasing the number of alternating layers of the first reflective film sublayer 431 and the second reflective film sublayer 432 in the structure of the first reflective film layer 43, the reflectivity can approach 100%. However, considering factors such as thin-film absorption, scattering damage in practical panels, and display panel thickness, the reflectivity will not reach 100%. This embodiment adopts a composite structure with alternating layers of the first reflective film sublayer 431 and the second reflective film sublayer 432. The first reflective film sublayer 431 uses a material with a higher refractive index compared to the second reflective film sublayer 432. The total number of layers is an odd number greater than or equal to 3 (i.e., the combined layers of the first and second reflective film sublayers sum to ≥3), with both the top and bottom layers of the first reflective film layer being the first reflective film sublayer. The extinction coefficient for visible light is sufficiently small, and the structure exhibits strong mechanical toughness. The first reflective film sublayer 431 employs a high-refractive-index material, with each layer's thickness preferably being ¼ of the wavelength of the reflected light. This design maximizes total reflection when light passes through the reflective layer combination, fully redirecting downward-propagating light to the light-emitting surface of the display panel, thereby enhancing light utilization efficiency and panel brightness.

As shown in FIGS. 5-1 to 5-2, in this embodiment, the thickness of the metal plating layer 45 ranges from 300 nm to 5000 nm.

Optionally, the thickness of the metal plating layer 45 is preferably greater than or equal to that of the first reflective film layer 43. This ensures that when the light-emitting chip 2 is placed on the upper surface of the metal plating layer 45, the bottom of the light-emitting chip 2 remains higher than the first reflective film layer 43. Consequently, most of the light emitted from the sides of the light-emitting chip 2 propagates above the first reflective film layer 43, improving light extraction efficiency. Additionally, this prevents the light-emitting chip 2 from contacting or exerting pressure on the first reflective film layer 43, thereby avoiding damage to both the first reflective film layer 43 and the light-emitting chip 2.

In other examples, the thickness of the metal plating layer 45 may also be less than that of the first reflective film layer 43. However, the difference between the upper surface of the metal plating layer 45 and the upper surface of the first reflective film layer 43 should not exceed 10 μm. Otherwise, during stencil printing of solder paste, the upper surface of the metal plating layer 45 may not fully adhere to the stencil apertures, leading to reduced consistency in solder paste printing. Since solder paste, typically 20 μm thick, is printed on the metal plating layer 45 for bonding with the light-emitting chip, the bottom surface of the light-emitting chip can still remain above the first reflective film layer 43 after soldering.

Within a certain range, the thicker the metal plating layer 45 on the second pad area 44, the stronger the bonding force between the light-emitting chip and the fourth circuit layer 42 after soldering, resulting in higher push force values. However, if the thickness of the metal plating layer 45 exceeds a certain limit, it may cause cracking or detachment from the metal of the fourth circuit layer. Conversely, if the metal plating layer 45 is too thin, it may fully alloy with the solder paste (i.e., form an alloy with the solder paste) and also detach easily from the metal of the fourth circuit layer. Therefore, in this embodiment, the thickness of the metal plating layer 45 is preferably between 300 nm and 5000 nm, with an optimal range of 400 nm to 3000 nm.

As shown in FIG. 5-1, in this embodiment, the metal plating layer 45 is selected from one or two of Cu (copper) layer, Au (gold) layer, or Ni (nickel) layer. If the metal plating layer 45 is a Cu layer, its primary function is to elevate the second pad area for easier solder paste printing. To prevent oxidation of the Cu layer, a Au layer or Ni layer may be additionally coated over the copper layer. If the metal plating layer 45 is a Au layer or Ni layer, its main purpose is to prevent oxidation of the second pad area while also elevating it. Optionally, Cu, Au, and Ni layers all exhibit excellent conductivity and soldering performance.

In other examples, conductive adhesive may be applied above the metal plating layer 45 to connect the light-emitting chip 2 to the pad. Additionally, other conductive adhesive materials with bonding properties can be used to solder the light-emitting chip 2 onto the pad.

As shown in FIG. 5-1, in this embodiment, the display module includes an encapsulation layer, which includes a fourth encapsulation adhesive layer formed by a plurality of third lenses 47. Specifically, the light-emitting chip 2 is equipped with a third lens 47 that envelops the light-emitting chip and forms a protruding curved surface above it, facilitating the diffusion of light emitted by the chip. Optionally, transparent molding adhesive can be dispensed above the light-emitting chip 2, which solidifies to form the third lens 47, achieving both optical design and chip protection effects.

In some examples, the edges of the third lens 47 cover the first reflective film layer 43; the lens fills the gap between the light-emitting chip 2 and the substrate, enhancing the hermeticity of the light-emitting chip 2.

### Embodiment 5

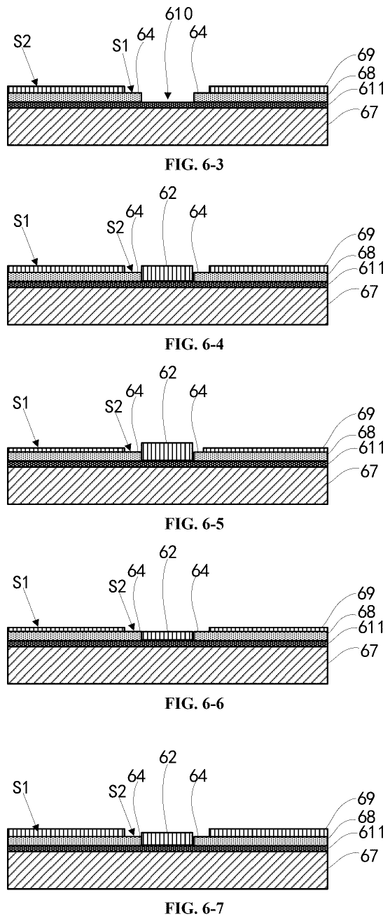

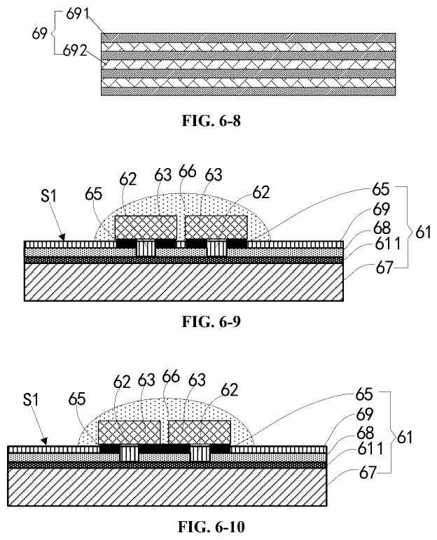

In related technologies, display modules fabricated using Mini LED chips can achieve local dimming, significantly improving display quality and gaining market favor. In prior art, the structure of the display module is illustrated in FIG. 6-1, which includes a circuit board 51. The circuit board 51 includes a circuit layer 510 that forms circuits and pads, with an ink layer 511 on the upper surface of the circuit layer 510, exposing the pads. Mini LED chips 512 are soldered onto corresponding pairs of pads on the circuit board 51 on the ink layer 511. A lens adhesive is then dispensed above the Mini LED chips 512 to form lenses 513. Due to the high viscosity of the lens adhesive, after the adhesive is dispersed onto the Mini LED chips 512, air trapped between the bottom of the Mini LED chips 512 and the pads is difficult to expel, creating an air layer space 514. During prolonged use, moisture infiltrates the lens 513 and enters this air layer space 514, providing a pathway for electrochemical migration. Under voltage, ions migrate between the pads, forming metallic dendrites, which can easily cause short circuits in the Mini LED chips 512.

To address the above issues, this embodiment provides a novel display module. It should be understood that the display module in this embodiment can be implemented independently of other embodiments or combined with them without conflict. For clarity, the following describes this display module with examples.

The display module provided in this embodiment can be applied to various display devices and includes a light panel; of course, this light panel can also be used in various lighting applications. Referring to FIGS. 6-2 to 6-4, the light panel of the display module includes a substrate 61 and a plurality of light-emitting chips arranged on it (a single light-emitting chip is used as an example below). In this embodiment:
the light-emitting chip in this embodiment may be, but is not limited to, a Mini flip-chip LED 63; the positive and negative electrodes of the Mini flip-chip LED 63 are electrically connected to the corresponding two fifth pads 64 on the substrate 61; for example, as illustrated in FIG. 6-2, the positive and negative electrodes of the Mini flip-chip LED 63 are electrically connected to the corresponding two fifth pads 64 on the substrate 61 (see FIG. 6-3 or FIG. 6-4) via solder 65 (which can also be replaced with conductive adhesive, etc.; the solder may include, but is not limited to, various solder pastes).

The lamp board further includes a filling layer 62 with insulating properties located between the two fifth pads 64. The side of the filling layer 62 close to the Mini flip-chip LED 63 is not lower than the upper surface S1 of the fifth pads 64. That is, the filling layer 62 is flush with or slightly higher than the upper surface S1.

The lamp board further includes a fifth encapsulation adhesive layer composed of several fourth lenses. As shown in FIG. 6-2, the fourth lens 66 is formed on each Mini flip-chip LED 63 by dispensing.

In this embodiment, the filling layer 62 is flush with or slightly higher than the upper surface S1. On one hand, this can block the direct path between the two fifth pads 64, preventing the formation of a short circuit between the two fifth pads 64 due to solder or conductive adhesive during the connection of the positive and negative electrodes of the Mini flip-chip LED 63 to the corresponding fifth pads 64 on the substrate 61, thereby improving reliability. On the other hand, the filling layer 62 can minimize the formation of an air layer space between the two fifth pads 64 after the fourth lens 66 is formed on the Mini flip-chip LED 63 by dispensing, thus avoiding the formation of metal dendrites between the two fifth pads during use, which could cause a short circuit in the Mini flip-chip LED 63. For example, in some optional examples, as shown in FIGS. 6-3 and 6-4, the upper surface S1 of the fifth pad 64 is lower than the upper surface S2 of the substrate 61. The side of the filling layer 62 close to the Mini flip-chip LED 63 can be specifically set to be not lower than the upper surface S2, i.e., flush with or slightly higher than the upper surface S2. In this case, as shown in FIG. 6-2, the filling layer 62 fills at least the majority of the gaps between the bottom of the Mini flip-chip LED 63 and the two fifth pads, preventing the formation of a moisture space here and thereby cutting off the electrochemical migration path between the fifth pads. Under these conditions, even if ions are generated on the fifth pads under voltage, the electrochemical migration path between the fifth pads is blocked by the filling layer 62, preventing the formation of metal dendrites between the fifth pads and thus avoiding a short circuit in the Mini flip-chip LED 63. This further enhances the reliability of the lamp board (i.e., the display module).

For ease of understanding, the following describes the structure of the substrate 61 using an optional example. As shown in FIGS. 6-2 to 6-4, the substrate 61 includes a fourth insulating base layer 67, a fifth circuit layer 68 disposed on the fourth insulating base layer 67, and an insulating cover layer 69 disposed on the fifth circuit layer 68. The side of the insulating cover layer 69 away from the fifth circuit layer 68 forms the upper surface S2 of the substrate 61. The fifth pad 64 is formed by the area of the fifth circuit layer 68 exposed through the insulating cover layer 69, with an insulating slot 610 between two fifth pads 64. A filling layer 62 fills the insulating slot 610 and does not exceed the upper surface S1 of the fifth pad 64.

It should be understood that the fourth insulating base layer 67 in this embodiment can be equivalently replaced with a conductive base material layer, such as but not limited to an aluminum base layer, FR4 base layer, or copper base layer. If the fourth insulating base layer 67 is replaced with a conductive insulating base layer (see FIG. 6-2), the substrate 61 also includes an insulating barrier layer 611 to isolate the fourth insulating base layer 67 from the fifth circuit layer 68. In other embodiments, the fourth insulating base layer 67 may also use a glass insulating base layer or ceramic insulating base layer, in which case the insulating barrier layer 611 can be optionally included or omitted.

The fifth circuit layer 68 in this embodiment can be made of but is not limited to metal conductive materials, such as copper circuit layer, titanium circuit layer, aluminum circuit layer, molybdenum circuit layer, or silver circuit layer. In some optional examples, the fabrication method for the fifth circuit layer 68 may involve depositing a metal layer on the fourth insulating base layer 67, with a thickness ranging from 400 nm to 6000 nm, followed by processes such as vapor deposition, exposure, and etching to form the fifth circuit layer 68. In the example shown in FIG. 6-2, since an insulating barrier layer 611 is also present on the fourth insulating base layer 67, the fabrication method for the fifth circuit layer 68 may involve depositing a metal layer on the insulating barrier layer 611, with a thickness ranging from 400 nm to 6000 nm, followed by processes such as vapor deposition, exposure, and etching to form the fifth circuit layer 68.

In some optional examples, the materials of the filling layer 62 and the insulating cover layer 69 may be the same, such as both being an ink layer (e.g., white ink layer) or a second reflective film layer. To enhance light extraction efficiency, the reflectivity of the second reflective film layer in this embodiment is greater than 99.5%.

In some other examples of this embodiment, the materials of the filling layer 62 and the insulating cover layer 69 may also differ. For instance, the filling layer 62 could be a green ink layer or an adhesive layer, while the insulating cover layer 69 could be a white ink layer or a second reflective film layer.

It is evident that in this embodiment, the materials of the filling layer 62 and the insulating cover layer 69 can be flexibly selected and configured according to requirements, offering good flexibility and versatility. For ease of understanding, the following will illustrate some specific application examples.

In other application examples, the filling layer 62 and the upper surface S2 of the substrate 61 may not be flush. For example, as shown in FIG. 6-5, the side of the filling layer 62 near the Mini flip-chip LED 63 is higher than the upper surface S2 of the substrate 61, but the overall thickness of the filling layer 62 does not affect the reliable connection of the Mini flip-chip LED 63 to the corresponding two fifth pads 64. Another example, as shown in FIG. 6-6, the side of the filling layer 62 near the Mini flip-chip LED 63 is flush with the upper surface S1 of the fifth pad 64 but lower than the upper surface S2 of the substrate 61. Yet another example, as shown in FIG. 6-7, the side of the filling layer 62 near the Mini flip-chip LED 63 is higher than the upper surface S1 of the fifth pad 64 but lower than the upper surface S2 of the substrate 61. In the examples shown in FIGS. 6-6 and 6-7, although a certain air layer may still form between the two fifth pads 64 after dispensing adhesive to form the fourth lens 66 on the Mini flip-chip LED 63, the arrangement of the filling layer 62 can minimize this air layer region. This helps avoid the formation of metal dendrites between the two fifth pads during use, which could cause a short circuit in the Mini flip-chip LED 63, thereby improving the reliability of the light panel.

In some examples, the filling layer 62 can be configured to have no gaps with the Mini flip-chip LED 63 and the fourth lens 66. For instance, the filling layer 62 can be formed between the corresponding two fifth pads 64 through, but not limited to, a dispensing process (the filling layer 62 can use the same adhesive material as that for forming the fourth lens 66). The resulting filling layer 62 has no gaps with the subsequently bonded Mini flip-chip LED 63 or the fourth lens 66 formed on the Mini flip-chip LED 63, completely avoiding the formation of the aforementioned air layer and further enhancing the reliability of the light panel.

In the above examples, to ensure that the overall thickness of the filling layer 62 does not affect the reliable connection between the Mini flip-chip LED 63 and the corresponding two fifth pads 64 while also maximizing the filling of the gap between the bottom of the Mini flip-chip LED 63 and the two fifth pads 64, the thickness of the filling layer 62 can be flexibly adjusted based on the specific dimensions of the gap the bottom of the Mini flip-chip LED 63 and the two fifth pads 64. For instance, according to the common size of Mini flip-chip LEDs 63, the thickness of the filling layer can be set between 30 μm and 60 μm.

In the above examples, if the insulating cover layer 69 is the second reflective film layer, its thickness can be set to less than 10 μm. A metal plating layer can also be pre-applied on the fifth pad 64 to facilitate soldering with the electrodes of the Mini flip-chip LED 63. Since the thickness of the insulating cover layer 69 is less than 10 μm, when the stencil prints solder paste on the fifth pad 64, the contact between the stencil apertures and the metal plating layer on the fifth pad 64 is more thorough, making soldering easier. Additionally, the reflectivity of the second reflective film layer exceeds 99.5%, significantly improving the light efficiency of the lamp board.

In some optional examples, if the insulating cover layer 69 is the second reflective film layer, its thickness can be set to less than 3 μm. Compared to using an ink layer to enhance reflectivity, where the ink layer typically has a thickness of 20 μm to 50 μm, the excessive thickness of the ink layer can affect the chip bonding yield. In contrast, the insulating cover layer 69 in this embodiment, with a thickness of less than 3 μm, allows the stencil to easily print solder paste on the fifth pad area, thereby improving the chip bonding yield.

As shown in FIGS. 6-8, in some optional examples, the second reflective film layer may include a third reflective film sublayer 691 and a fourth reflective film sublayer 692 with different reflectivities. The second reflective film layer is formed by alternately stacking the third reflective film sublayer 691 and the fourth reflective film sublayer 692. This structure ensures that the second reflective film layer has high reflectivity.

In some application examples, the thickness of the third reflective film sublayer 691 ranges from 100 nm to 500 nm, and the thickness of the fourth reflective film sublayer 692 ranges from 200 nm to 1000 nm. The number of alternating stacked layers of the third reflective film sublayer 691 and the fourth reflective film sublayer 692 is 3 to 21. This ensures that the second reflective film layer exhibits high reflectivity for light in the wavelength range of 400 nm to 490 nm, with an average reflectivity ≥99.5%.

In this embodiment, the refractive index of the third reflective film sublayer 691 is higher than that of the fourth reflective film sublayer 692. The third reflective film sublayer 691 is selected from one or two of TiO₂ film, ZrO₂ film, HfO₂ film, or Ta₂O₅ film, while the fourth reflective film sublayer 692 is selected from SiO₂ film.

In this embodiment, the structure of the second reflective film layer achieves a reflectivity close to 100% by increasing the number of alternating stacked layers of the third reflective film sublayer 691 and the fourth reflective film sublayer 692. However, considering factors such as film absorption, scattering in practical light panels, and the thickness of the display panel, the reflectivity does not reach 100%. This embodiment employs a composite structure with alternating layers of the third reflective film sublayer 691 and the fourth reflective film sublayer 692. The third reflective film sublayer 691 uses a material with a higher refractive index compared to the fourth reflective film sublayer 692. The total number of layers is an odd number greater than or equal to 3 (i.e., the total number of the layers of the third and fourth reflective film sublayers is ≥3), with both the bottommost and topmost layers of the second reflective film layer being the third reflective film sublayer 691. The extinction coefficient in the visible light range is sufficiently small, and the structure exhibits strong mechanical flexibility. The third reflective film sublayer 691 uses a high-refractive-index material, and the thickness of each second reflective film layer is preferably ¼ of the wavelength of the reflected light. This design maximizes total reflection when light passes through the reflective layer combination, fully redirecting downward-propagating light to the light-emitting surface of the panel, thereby improving light utilization and panel brightness.

In this embodiment, the insulating cover layer 69 serves as the second reflective film layer. When a metal plating layer is preset on the fifth pad 64, in some examples, the thickness of the metal plating layer may be greater than or equal to that of the second reflective film layer. This ensures that when the Mini flip-chip LED 63 is placed on the upper surface of the metal plating layer, the bottom of the Mini flip-chip LED 63 remains higher than the second reflective film layer. As a result, most of the light emitted from the sides of the Mini flip-chip LED 63 is positioned above the second reflective film layer, improving light extraction efficiency. Additionally, this prevents the Mini flip-chip LED 63 from contacting or exerting pressure on the second reflective film layer, avoiding damage to both the second reflective film layer and the Mini flip-chip LED 63. In other examples, the thickness of the metal plating layer may be less than that of the second reflective film layer, but the difference between the upper surface of the metal plating layer and the upper surface of the reflective film layer should not exceed 10 μm. Otherwise, during stencil printing of solder paste, the upper surface of the metal plating layer may not fully adhere to the stencil apertures, leading to reduced consistency in solder paste printing. Since solder paste, typically 20 μm thick, is printed on the metal plating layer for bonding with the LED chip, the bottom surface of the Mini flip-chip LED 63 can still remain above the second reflective film layer after the Mini flip-chip LED 63 is soldered to the soldering layer with solder paste. It should be understood that within a certain range, the thicker the metal plating layer on the fifth pad 64, the stronger the bonding force between the Mini flip-chip LED 63 and the fifth circuit layer 68 after the Mini flip-chip LED 63 is soldered with solder paste. Therefore, in this embodiment, when presetting the metal plating layer on the fifth pad 64, its thickness is set between 300 nm and 5000 nm, preferably 400 nm to 3000 nm. The metal plating layer in this embodiment is selected from, but not limited to, copper, gold, nickel, or silver layers, or a combination thereof. If the metal plating layer is a copper layer, its primary function is to elevate the fifth pad area for easier solder paste printing in the fifth pad area. To prevent oxidation of the copper layer, a gold or nickel layer may be additionally applied over the copper layer. If the metal plating layer is gold or nickel, its main purpose is to prevent oxidation of the fifth pad area while also raising the height of the fifth pad area.

In this embodiment, a fourth lens 66 is formed on the Mini flip-chip LED 63 through a dispensing process. The fourth lens 66 envelops the Mini flip-chip LED 63 and forms a protruding curved surface above the Mini flip-chip LED 63 to facilitate the diffusion of light emitted by the Mini flip-chip LED 63. In some examples, transparent molding adhesive may be dispensed above the Mini flip-chip LED 63, or a mixed molding adhesive containing at least one of phosphor powder, quantum dots, or diffusion powder may be formed as needed. After curing, the adhesive forms the fourth lens 66, achieving both optical design and chip protection effects.

In some optional examples, a plurality of light-emitting units may be arranged on the substrate 61, with each light-emitting unit containing the same number of Mini flip-chip LEDs 63. For instance, each light-emitting unit may include only one Mini flip-chip LED 63, as shown in FIG. 6-2. Alternatively, each light-emitting unit may include at least two Mini flip-chip LEDs 63, all covered by the fourth lens 66, as illustrated in FIGS. 6-9 and 6-10. In FIG. 6-9, the fifth pads corresponding to the Mini flip-chip LEDs 63 are independent, and each Mini flip-chip LED 63 is connected to its corresponding fifth pad via solder 65 or conductive adhesive. The main difference between FIG. 6-10 and FIG. 6-9 is that in FIG. 6-10, at least two Mini flip-chip LEDs 63 in the light-emitting unit share at least one fifth pad.

In some optional examples, among the light-emitting units on the substrate 61, at least some units may contain different numbers of Mini flip-chip LEDs 63.

It should also be understood that in this embodiment, at least one of the light emission color or size of the Mini flip-chip LEDs 63 in each light-emitting unit on the substrate 61 may be set to be the same or different as needed. Specific configurations can be flexibly adjusted based on the application scenario of the light panel, and further details are omitted here.

This embodiment further provides a display device, which includes a display controller and the aforementioned display module. The display controller is connected to the display module and can control the operation of the display module. The display device may include, but is not limited to, display devices for mobile terminals, televisions, PCs, wearable devices, automotive devices, advertising devices, and other end-user equipment.

This embodiment further provides a lighting device, which includes a lighting controller and the aforementioned light panel. The lighting controller is connected to the light panel and can control the operation of the light panel.

It should be understood that each of the aforementioned embodiments of this application can be implemented independently or in combination with partial embodiments or technical features from various embodiments. Moreover, the application of this invention is not limited to the examples provided above. For those skilled in the art, improvements or modifications can be made based on the above descriptions, and all such improvements and modifications shall fall within the protection scope of the appended claims.

What is claimed is:

1. A light-emitting device, comprising:
a substrate having a mounting surface, the mounting surface being provided with a first pad region corresponding to a light-emitting chip;
a plurality of light-emitting chips fixed on the mounting surface and electrically connected with corresponding second pads in the first pad region;
at least one reinforcing member fixedly protruding from the mounting surface, the reinforcing member being provided with a through-hole penetrating its two sides; and
an encapsulant layer comprising a second encapsulant, the second encapsulant being disposed on the mounting surface and encapsulating the light-emitting chips and the reinforcing member therein;
wherein a portion of the second encapsulant fills and penetrates the through-hole, and the second encapsulant inside and outside the through-hole is integrally cured, such that light emitted from the light-emitting chip is emitted through the encapsulant layer.

2. The light-emitting device according to claim 1, wherein the substrate comprises a first insulating base layer, a first circuit layer, and a solder mask layer sequentially stacked, the first circuit layer being provided with a plurality of first pads respectively corresponding to the plurality of light-emitting chips;
wherein the solder mask layer is provided with a plurality of openings corresponding to the first pads, and each first pad is exposed through a respective opening, such that the light-emitting chips are electrically connected to the corresponding first pads through the openings;
wherein the solder mask layer further comprises a plurality of fixing grooves respectively surrounding the openings; and
wherein the encapsulant layer comprises a first encapsulant layer formed by a plurality of first lenses, each first lens being formed by filling a first encapsulant into a corresponding opening, a portion of the first encapsulant forming the first lens being accommodated in the corresponding fixing groove.

3. The light-emitting device according to claim 2, wherein a bottom of the fixing groove extends to the first circuit layer or the first insulating base layer;
wherein a bottom of the fixing groove extends to the first insulating base layer, and the solder mask layer at an edge of the fixing groove extends toward the first insulating base layer to cover the first circuit layer;
wherein at least one of the fixing grooves comprises a closed annular groove; and
wherein the fixing groove comprises at least two annular grooves sequentially nested.

4. The light-emitting device according to claim 3, wherein the fixing groove is annular or square-ring shaped, and the corresponding opening is located in a central region of the fixing groove;
wherein a minimum width of the fixing groove is 0.1 mm and a maximum width is 1.0 mm; and
wherein a bottom width of the fixing groove is greater than a top width thereof.

5. The light-emitting device according to claim 1, wherein a number of the reinforcing members corresponding to each first pad region is greater than or equal to 2, and the reinforcing members are symmetrically arranged about a geometric center of the light-emitting chip;
wherein the reinforcing members are integrally formed with and fixed to the substrate;
wherein the reinforcing members are chamfered at openings of the through-holes; and
wherein the reinforcing members are made of a transparent material, or are made of a non-transparent material with a reflective layer provided on a surface thereof.

6. The light-emitting device according to claim 5, wherein a cross-sectional area of the through-hole is greater than or equal to 50% of a cross-sectional area of the reinforcing member in a corresponding direction;
wherein an extending direction of the through-hole is parallel to the mounting surface; and
wherein a portion of a boundary of the through-hole is formed by the mounting surface.

7. The light-emitting device according to claim 1, wherein the substrate comprises a second insulating base layer having a first surface, a second surface opposite the first surface, and a plurality of side surfaces connecting the first and second surfaces;
wherein the first surface is provided with a second circuit layer, the second surface is provided with a third circuit layer, and at least one side surface is provided with a side-surface circuit layer;
wherein the side-surface circuit layer at least partially connects the second circuit layer and the third circuit layer;
wherein the plurality of light-emitting chips are mounted on the second circuit layer; and
wherein the encapsulant layer comprises a third encapsulant layer covering the first surface of the second insulating base layer, the light-emitting chips, and at least a portion of the side-surface circuit layer, the third encapsulant layer having a top surface orthogonal to an extension plane of the side surfaces, and a side surface connected at a right angle to the top surface.

8. The light-emitting device according to claim 7, wherein the third encapsulant layer extends to the second surface and is flush with the surface of the second surface;
wherein the second circuit layer and the side-surface circuit layer are covered with a circuit protection layer; and
wherein the third encapsulant layer covers at least a portion of the circuit protection layer on the second circuit layer and the side-surface circuit layer.

9. The light-emitting device according to claim 1, wherein the substrate comprises a third insulating base layer and a fourth circuit layer disposed on the third insulating base layer;
wherein the fourth circuit layer is provided with at least two second pad regions spaced apart from each other, and surfaces of the second pad regions are plated with a metal coating, an upper end of the metal coating being exposed to form a fourth pad;
wherein a gap between the at least two second pad regions and a surface of the third insulating base layer forms a groove;
wherein a first reflective film layer is disposed on the fourth circuit layer and on the surface of the third insulating base layer located in the groove; and
wherein the light-emitting chip is disposed on the metal coating with a bottom surface higher than the first reflective film layer.

10. The light-emitting device according to claim 9, wherein a thickness of the first reflective film layer is less than or equal to 10 μm and is disposed adjacent to an edge of the metal coating.

11. The light-emitting device according to claim 9, wherein the second insulating base layer and the third insulating base layer form a directly stacked structure.

12. The light-emitting device according to claim 9, wherein the first reflective film layer comprises a first reflective sub-layer and a second reflective sub-layer having different refractive indices, the first and second reflective sub-layers being alternately stacked.

13. The light-emitting device according to claim 1, wherein the plurality of light-emitting chips are mini flip-chip LED chips.

14. The light-emitting device according to claim 11, wherein the substrate comprises a fourth insulating base layer, a fifth circuit layer disposed on the fourth insulating base layer, and an insulating cover layer disposed on the fifth circuit layer;
wherein a surface of the insulating cover layer away from the fifth circuit layer forms an upper surface of the substrate;
wherein a fifth pad is formed by a region of the fifth circuit layer exposed through the insulating cover layer; and
wherein an insulating trench is provided between two fifth pads.

15. The light-emitting device according to claim 11, wherein the insulating cover layer is a reflective film layer having a reflectivity greater than 99.5%.

16. A method for manufacturing a light-emitting device, comprising the following steps of:
providing a substrate;
arranging a plurality of light-emitting chips on a front side of the substrate;
forming an encapsulation layer on the substrate to cover each of the light-emitting chips, wherein the encapsulation layer allows light from the light-emitting chips to pass through.

17. The method for manufacturing a light-emitting device according to claim 16, wherein,
the provided substrate comprises a first insulating base layer, a first circuit layer, and a solder resist layer sequentially stacked; the first circuit layer is provided with a plurality of sets of first pads, the solder resist layer is provided with a plurality of window openings corresponding to the first pads, and each set of first pads is exposed through the corresponding window opening; the solder resist layer is further provided with a plurality of fixing grooves respectively surrounding each of the window openings;
the step of arranging a plurality of light-emitting chips on a front side of the substrate comprises: fixing and arranging the light-emitting chips within the window openings and electrically connecting the light-emitting chips to the corresponding first pads;
the step of forming an encapsulation layer on the substrate to cover each of the light-emitting chips comprises: filling a first encapsulant above the corresponding window opening to integrally form a first lens, wherein part of the first encapsulant forming the first lens fills the fixing groove.

18. The method for manufacturing a light-emitting device according to claim 16, wherein,
the provided substrate comprises a mounting surface, on which a first pad area corresponding to the light-emitting chips is arranged; the step of arranging a plurality of light-emitting chips on a front side of the substrate comprises fixing the light-emitting chips on the mounting surface and electrically connecting the light-emitting chips to corresponding second pads in the first pad area; the provided substrate further comprises a reinforcing member fixedly protruding from the mounting surface, the reinforcing member being provided with a through hole penetrating both sides of the reinforcing member;
the step of forming an encapsulation layer on the substrate to cover each of the light-emitting chips on the substrate comprises: applying an uncured encapsulation material to envelop the light-emitting chips and the reinforcing member, with at least part of the encapsulation material filling the through hole; then curing the encapsulation material to form a second encapsulation adhesive layer, wherein the encapsulation material inside and outside the through hole is integrally cured.

19. The method for manufacturing a light-emitting device according to claim 16, wherein,
the provided substrate comprises a second insulating base layer, a second circuit layer disposed on a first surface of the second insulating base layer, and a third circuit layer disposed on a second surface of the second insulating base layer opposite to the first surface; the second insulating base layer is made of a glass material, and the second circuit layer comprises a plurality of third pads corresponding to electrodes of the light-emitting chips; wherein a process edge at a periphery of the substrate where a side circuit layer needs to be formed are removed, exposing a side surface of the second insulating base layer and forming the side circuit layer at the side surface of the second insulating base layer for electrically connecting at least part of circuits between the second circuit layer and the third circuit layer;
the step of arranging a plurality of light-emitting chips on a front side of the substrate comprises: mounting the light-emitting chips on the plurality of third pads of the second circuit layer;
the step of forming an encapsulation layer to cover each of the light-emitting chips on the substrate comprises: placing a carrier board on a side of the substrate where the process edge is removed, with a gap between a side of the carrier board and the side of the substrate; providing a mold and a semi-solid encapsulation adhesive film, placing the mold on the substrate and the carrier board so that at least part of the mold abuts against the carrier board, arranging the semi-solid encapsulation adhesive film in the mold and performing vacuum hot pressing to melt the semi-solid encapsulation adhesive film to cover the first surface of the substrate, the light-emitting chips, and at least part of the carrier board to form a third encapsulation adhesive layer, wherein an upper surface of the third encapsulation adhesive layer is orthogonal to an extended plane of the side of the substrate, and curing to obtained the cured third encapsulation adhesive layer; and
after obtaining the cured third encapsulation adhesive layer, the method further comprises: using a cutting tool to remove the carrier board and the third encapsulation adhesive layer attached to the carrier board as well as excess process edges along a gap between the side of the substrate and the carrier board, parallel to the side of the substrate.

20. The method for manufacturing the light-emitting device according to claim 16, wherein,
the provided substrate comprises a second insulating base layer, a second circuit layer disposed on a first surface of the second insulating base layer, and a third circuit layer disposed on a second surface of the second insulating base layer opposite to the first surface, wherein the second insulating base layer is made of a glass material, and the second circuit layer is provided with a plurality of third pads corresponding to electrodes of the light-emitting chips; wherein process edges at a periphery of the substrate are all removed, exposing a side of the second insulating base layer, and a side circuit layer is disposed on at least part of the side of the second insulating base layer for electrically connecting at least part of circuits between the second circuit layer and the third circuit layer;
the step of arranging a plurality of light-emitting chips on a front side of the substrate comprises: placing the light-emitting chips on the plurality of third pads of the second circuit layer;
the step of forming an encapsulation layer to cover each of the light-emitting chips on the substrate comprises: placing carrier boards on all sides of the periphery of the substrate, with a gap existing between a side of the carrier board and the side of the substrate; providing a mold and a semi-solid encapsulation adhesive film, placing the mold on the substrate and the carrier board so that at least part of the mold abuts against the carrier board, placing the semi-solid encapsulation adhesive film in the mold and performing vacuum hot pressing to melt the semi-solid encapsulation adhesive film to cover the first surface of the substrate, the light-emitting chips, at least part of the carrier board, and at least part of the gap between the substrate and the carrier board to form a third encapsulation adhesive layer, wherein an upper surface of the third encapsulation adhesive layer is orthogonal to an extended plane of the side of the substrate, and curing to obtain the cured third encapsulation adhesive layer;
after obtaining the cured third encapsulation adhesive layer, the method further comprises: using a cutting tool to remove the carrier board and the third encapsulation adhesive layer attached to the carrier board along the gap between the side of the substrate and the carrier board, parallel to the side of the substrate.
